(19) United States
(12) Patent Application Publication
(10) Pub. No.: US 2025/0248287 A1
(43) Pub. Date: Jul. 31, 2025

(54) DISPLAY DEVICE

(71) Applicant: Sony Semiconductor Solutions Corporation, Kanagawa (JP)

(72) Inventors: Koji Tanaka, Kanagawa (JP); Shintaro Yumoto, Kanagawa (JP); Masahiro Kawamura, Kanagawa (JP)

(21) Appl. No.: 18/992,372

(22) PCT Filed: Jul. 11, 2023
(86) PCT No.: PCT/JP2023/025528

§ 371 Date: Jan. 8, 2025

(30) Foreign Application Priority Data
Jul. 15, 2022 (JP) 2022-113750

(51) Int. Cl. H10K 59/80

(52) U.S. Cl. CPC H10K 59/879

(57) ABSTRACT

A display device includes: a light emitting element layer provided on a base; and a lens layer provided on a side opposite to the base across the light emitting element layer, the lens layer including a plurality of main lenses arranged in an array in a plane direction of the lens layer and an auxiliary lens provided on a side opposite to the light emitting element layer across the array of the plurality of main lenses, the auxiliary lens being located between adjacent main lenses among the plurality of main lenses in a plan view of the lens layer.

### FIELD

The present disclosure relates to a display device.

### BACKGROUND

There is known a display device in which a lens for light collection is provided for each pixel in order to efficiently extract light from a light emitting element (for example, Patent Literature 1).

### CITATION LIST

### Patent Literature

Patent Literature 1: WO 2020/080022 A

### SUMMARY

### Technical Problem

For example, in an edge portion of the pixel, light cannot be sufficiently collected by the lens so that light that cannot be extracted in a front direction of a pixel is generated in some cases. As a result, light extraction efficiency decreases.

One aspect of the present disclosure improves the light extraction efficiency.

### Solution to Problem

A display device according to one aspect of the present disclosure includes: a light emitting element layer provided on a base; and a lens layer provided on a side opposite to the base across the light emitting element layer, wherein the lens layer includes: a plurality of main lenses arranged in an array in a plane direction of the lens layer; and an auxiliary lens provided on a side opposite to the light emitting element layer across the array of the plurality of main lenses, and the auxiliary lens is located between adjacent main lenses among the plurality of main lenses in a plan view of the lens layer.

### BRIEF DESCRIPTION OF DRAWINGS

FIG. 1 is a view illustrating an example of a schematic configuration of a display device according to an embodiment.

FIG. 2 is a view illustrating an example of a traveling direction of light.

FIG. 3 is a view illustrating a comparative example.

FIG. 4 is a view illustrating an example of light extraction efficiency.

FIG. 5 is a view illustrating an example of a manufacturing method of the display device.

FIG. 6 is a view illustrating an example of the manufacturing method of the display device.

FIG. 7 is a view illustrating an example of the manufacturing method of the display device.

FIG. 8 is a view illustrating an example of the manufacturing method of the display device.

FIG. 9 is a view illustrating a variation of a cross-sectional structure.

FIG. 10 is a view illustrating a variation of the cross-sectional structure.

FIG. 11 is a view illustrating a variation of the cross-sectional structure.

FIG. 12 is a view illustrating a variation of the cross-sectional structure.

FIG. 13 is a view illustrating a variation of the cross-sectional structure.

FIG. 14 is a view illustrating a variation of the cross-sectional structure.

FIG. 15 is a view illustrating a variation of the cross-sectional structure.

FIG. 16 is a view illustrating a variation of the cross-sectional structure.

FIG. 17 is a view illustrating a variation of the cross-sectional structure.

FIG. 18 is a view illustrating a variation of a planar layout.

FIG. 19 is a view illustrating a variation of the planar layout.

FIG. 20 is a view illustrating a variation of the planar layout.

FIG. 21 is a view illustrating a variation of the planar layout.

FIG. 22 is a view illustrating a variation of the planar layout.

FIG. 23 is a view illustrating a variation of the planar layout.

FIG. 24 is a view illustrating a variation of the planar layout.

FIG. 25 is a view illustrating a variation of the planar layout.

FIG. 26 is a view illustrating a variation of the planar layout.

FIG. 27 is a view illustrating a modification.

FIG. 28 is a view illustrating a modification.

FIG. 29 is a view illustrating a modification.

FIG. 30 is a view illustrating a modification.

FIG. 31 is a view illustrating a modification.

FIG. 32 is a view illustrating a modification.

FIG. 33 is a view illustrating a modification.

FIG. 34 is a view illustrating a modification.

FIG. 35 is a view illustrating a modification.

FIG. 36 is a view illustrating a modification.

FIG. 37 is a view illustrating a modification.

FIG. 38 is a view illustrating a modification.

FIG. 39 is a view illustrating a modification.

FIG. 40 is a view illustrating a modification.

FIG. 41 is a view illustrating an application example.

FIG. 42 is a view illustrating an application example.

FIG. 43 is a view illustrating an application example.

FIG. 44 is a view illustrating an application example.

FIG. 45 is a view illustrating an application example.

FIG. 46 is a view illustrating an application example.

FIG. 47 is a view illustrating an application example.

FIG. 48 is a view illustrating an application example.

FIG. 49 is a view illustrating an example of a schematic configuration of a display device according to a further embodiment.

FIG. 50 is a view illustrating an example of a traveling direction of light.

FIG. 51 is a view illustrating an example of the traveling direction of light.

FIG. 52 is a view illustrating an example of the traveling direction of light.

FIG. 53 is a view illustrating an example of the traveling direction of light.

FIG. 54 is a view illustrating an example of a manufacturing method of the display device.

FIG. 55 is a view illustrating an example of the manufacturing method of the display device.

FIG. 56 is a view illustrating an example of the manufacturing method of the display device.

FIG. 57 is a view illustrating an example of the manufacturing method of the display device.

FIG. 58 is a view illustrating an example of the manufacturing method of the display device.

FIG. 59 is a view illustrating an example of the manufacturing method of the display device.

FIG. 60 is a view illustrating an example of the manufacturing method of the display device.

FIG. 61 is a view illustrating an example of the manufacturing method of the display device.

FIG. 62 is a view illustrating a variation of a cross-sectional structure.

FIG. 63 is a view illustrating a variation of the cross-sectional structure.

FIG. 64 is a view illustrating a variation of the cross-sectional structure.

FIG. 65 is a view illustrating a variation of the cross-sectional structure.

FIG. 66 is a view illustrating a variation of a planar layout.

FIG. 67 is a view illustrating a variation of the planar layout.

FIG. 68 is a view illustrating a variation of the planar layout.

FIG. 69 is a view illustrating a variation of the planar layout.

FIG. 70 is a view illustrating a variation of the planar layout.

FIG. 71 is a view illustrating a variation of the planar layout.

FIG. 72 is a view illustrating a variation of the planar layout.

### DESCRIPTION OF EMBODIMENTS

Hereinafter, embodiments of the present disclosure will be described in detail with reference to the drawings. Note that the same elements are denoted by the same reference signs in each of the following embodiments, and a repetitive description thereof will be omitted.

The present disclosure will be described in the following item order.
0. Introduction
1. Embodiment
2. Variations of Cross-Sectional Structure
3. Variations of Planar Layout
4. Example of Effects
5. Other Modifications
6. Application Examples
7. Further Embodiment
8. Variations of Cross-Sectional Structure
9. Variations of Planar Layout

### 0. Introduction

There is a display device that includes a lens for light collection (for example, an on-chip microlens) for each pixel in order to improve light extraction efficiency in a front direction. The area of the lens is desirably set to a size that allows the entire light from a light emitting element to be incident thereon, but is limited since an adjacent pixel is also provided with a lens.

In particular, in a portion spaced apart from the center of the pixel, for example, in an edge portion of the pixel, light cannot be sufficiently collected by the lens so that light is not extracted in the front direction of the pixel in some cases. This light can also be said to be leakage light that does not contribute to front luminance. As the leakage light is generated, the light extraction efficiency decreases, and eventually light emission efficiency decreases.

Note that the light extraction efficiency may be understood to mean a ratio of light effectively extracted to the outside to (the amount of) light from the light emitting element in the pixel. The light emission efficiency may be understood to mean conversion efficiency indicating how effectively light is output to the outside with respect to (the amount of) current supplied to the light emitting element. The light emission efficiency may be proportional to the light extraction efficiency.

According to the disclosed technology, the light extraction efficiency can be improved, and eventually the light emission efficiency can be improved.

### 1. Embodiment

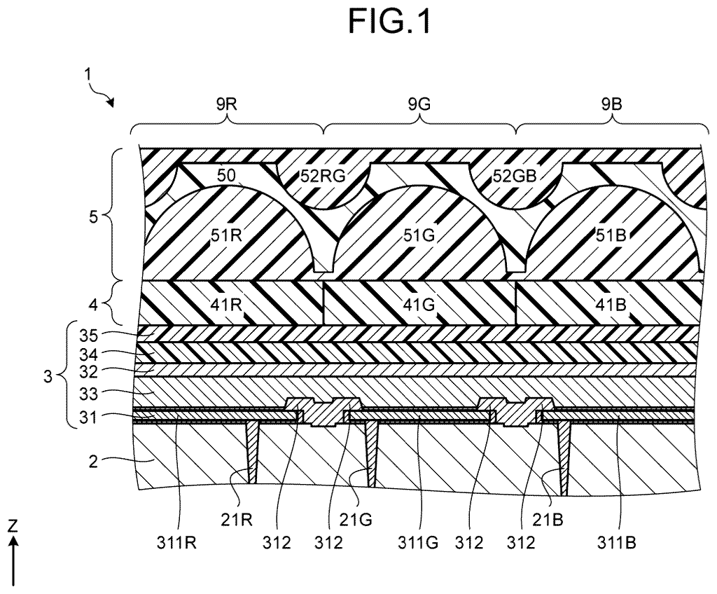

FIG. 1 is a view illustrating an example of a schematic configuration of a display device according to an embodiment. A partial cross section of a display device 1 is schematically illustrated. The display device 1 emits light in a front direction (forward). The front direction of the display device 1 is illustrated as a Z-axis positive direction.

The display device 1 includes a plurality of pixels 9 (corresponding to reference sign 9R and the like in the drawing). The plurality of pixels 9 are arranged in an array (for example, a two-dimensional matrix) in a plane direction orthogonal to a Z-axis direction. Examples of the pixel arrangement include a delta arrangement, a square arrangement, and the like, but are not limited thereto. FIG. 1 illustrates, as the plurality of pixels 9, the pixel 9R that emits red light, a pixel 9G that emits green light, and a pixel 9B that emits blue light. Note that the pixel 9R, the pixel 9G, and the pixel 9B are sometimes referred to as subpixels. Unless otherwise specified, it is assumed that the plurality of pixels 9 include the pixel 9R, the pixel 9G, and the pixel 9B.

The display device 1 includes a base 2, a light emitting element layer 3, a color filter layer 4, and a lens layer 5. The base 2, the light emitting element layer 3, the color filter layer 4, and the lens layer 5 are provided in this order in the Z-axis positive direction.

The base 2 is formed on a semiconductor substrate such as a silicon substrate and supports the light emitting element layer 3. A material of the base 2 may be an insulating material such as SiO₂, SiN, or SiON.

Contact plugs 21 (corresponding to reference sign 21R and the like in the drawing) are formed in the base 2. The contact plugs 21 are provided for the pixels 9, respectively. The contact plug 21 of the pixel 9R is referred to as the contact plug 21R in the drawing. The contact plug 21 of the pixel 9G is referred to as a contact plug 21G in the drawing. The contact plug 21 of the pixel 9B is referred to as a contact plug 21B in the drawing. The contact plug 21 is formed so as to penetrate the base 2 in the Z-axis direction.

Although not illustrated in the drawing, a circuit element (a transistor, a wiring, or the like) for driving the light emitting element layer 3 is provided on a side opposite to the light emitting element layer 3 across the base 2. This circuit element is electrically connected to the light emitting element layer 3 via the contact plug 21.

The light emitting element layer 3 is provided on the base 2. Examples of a light emitting element included in the light emitting element layer 3 are an organic electro luminescence (EL) element, a light emitting diode (LED) element, and the like. Hereinafter, it is assumed that the light emitting element is the organic EL element.

The light emitting element layer 3 includes an electrode layer 31, an electrode layer 32, an organic layer 33, a protective layer 34, and a planarization layer 35. The electrode layer 31, the organic layer 33, the electrode layer 32, the protective layer 34, and the planarization layer 35 are provided in this order in the Z-axis positive direction.

The electrode layer 31 and the electrode layer 32 are a first electrode layer and a second electrode layer provided on opposite sides of the organic layer 33. The electrode layer 31 includes electrodes 311 (corresponding to reference sign 311R and the like in the drawing) for the pixels 9, respectively. The electrode 311 of the pixel 9R is referred to as the electrode 311R in the drawing. The electrode 311 of the pixel 9G is referred to as an electrode 311G in the drawing. The electrode 311 of the pixel 9B is referred to as an electrode 311B in the drawing. An electrode of the electrode layer 32 is provided in common over the plurality of pixels 9, in this example, over the pixel 9R, the pixel 9G, and the pixel 9B.

Note that an electrode edge film 312 having insulating properties is provided between an edge portion of each of the electrodes 311 of the electrode layer 31 and the organic layer 33 in the example illustrated in FIG. 1. A portion of the electrode 311 covered with the electrode edge film 312 is electrically isolated from the organic layer 33, and light emission of the organic layer 33 corresponding to this portion is suppressed.

The organic layer 33 includes an organic EL element. In this example, the organic layer 33 is configured to emit at least red light at the pixel 9R, at least green light at the pixel 9G, and at least blue light at the pixel 9B. For example, the organic layer 33 may be configured to emit light (for example, white light) including red light, green light, and blue light over all the pixel 9R, the pixel 9G, and the pixel 9B. The organic layer 33 may have a laminated structure in which a plurality of layers that emit beams of light of the respective colors are laminated.

The protective layer 34 is provided so as to cover the electrode layer 32. Examples of a material of the protective layer 34 are SiN, SiON, Al₂O₃, TiO₂, and the like.

The planarization layer 35 is provided between the protective layer 34 and the color filter layer 4. A refractive index of the planarization layer 35 may be higher than a refractive index of the protective layer 34. As a material of the protective layer 34, for example, a material obtained by adding TiO₂ to a base material formed of an acrylic resin, a material obtained by adding TiO₂ to a base material formed of the same material (excluding a pigment) as that of the color filter layer 4 to be described later, and the like can be used.

The color filter layer 4 is provided between the light emitting element layer 3 and the lens layer 5. The color filter layer 4 includes color filters 41 (corresponding to reference sign 41R and the like in the drawing) for the pixels 9, respectively. The color filter 41 of the pixel 9R is referred to as the color filter 41R in the drawing. The color filter 41R allows red light out of light from the light emitting element layer 3 to pass therethrough. The color filter 41 of the pixel 9G is referred to as a color filter 41G in the drawing. The color filter 41G allows green light out of the light from the light emitting element layer 3 to pass therethrough. The color filter 41 of the pixel 9B is referred to as a color filter 41B in the drawing. The color filter 41B allows blue light out of the light from the light emitting element layer 3 to pass therethrough.

As a material of the color filter layer 4, various known materials such as a color resist material may be used. The color filter layer 4 is made of, for example, a resin to which a colorant formed of a desired pigment or dye is added. By selecting a pigment or a dye, adjustment is performed such that light transmittance in a target wavelength range of red light, green light, blue light, or the like is higher and light transmittance in the other wavelength range is lower.

The lens layer 5 is provided on a side opposite to the base 2 across the light emitting element layer 3 (and the color filter layer 4). The lens layer 5 includes a base portion 50, a plurality of main lenses 51 (corresponding to reference sign 51R and the like in the drawing), and one or more auxiliary lenses 52 (corresponding to reference sign 52RG and the like in the drawing).

The base portion 50 includes a portion (portion filling a gap) located between the main lens 51 and the auxiliary lens 52. It can be said that an arrangement of the main lens 51 and the auxiliary lens 52 in the base portion 50, that is, relative positions of the main lens 51 and the auxiliary lens 52 are defined by the base portion 50.

The main lens 51 is provided for each of the pixels 9, and thus the plurality of main lenses 51 are arranged in an array in a plane direction of the lens layer 5. The main lens 51 of the pixel 9R is referred to as the main lens 51R in the drawing. The main lens 51 of the pixel 9G is referred to as a main lens 51G in the drawing. The main lens 51 of the pixel 9B is referred to as a main lens 51B in the drawing.

The main lens 51 brings a traveling direction of the light from the light emitting element layer 3 close to the front direction of the display device 1 (the Z-axis positive direction), that is, a front direction of the corresponding pixel 9. In this example, the main lens 51R brings a traveling direction of the red light from the color filter 4R close to the front direction of the pixel 9R. The main lens 51G brings a traveling direction of the green light from the color filter 4G close to the front direction. The main lens 51B brings a traveling direction of the blue light from the color filter 4B close to the front direction.

In the example illustrated in FIG. 1, the main lens 51 is a condenser lens having a convex shape (for example, a semicircular shape) protruding toward the side opposite to the light emitting element layer 3, that is, in the front direction (Z-axis positive direction). The main lens 51 may have a refractive index higher than a refractive index of the base portion 50. Various known materials including a resin and the like may be used.

The auxiliary lens 52 is provided on the side opposite to the light emitting element layer 3 across the array of the plurality of main lenses 51. When the lens layer 5 is viewed in plan view (viewed in the Z-axis direction), the auxiliary lens 52 is located between adjacent main lenses 51 among the plurality of main lenses 51. In this example, one auxiliary lens 52 is located between the adjacent main lenses 51. The auxiliary lens 52 between the main lens 51R and the main lens 51G is referred to as the auxiliary lens 52RG in the drawing. The auxiliary lens 52 between the main lens 51G and the main lens 51B is referred to as an auxiliary lens 52GB in the drawing.

The auxiliary lens 52 brings the traveling direction of the light from the corresponding main lens 51 close to the front direction of the display device 1 (the Z-axis positive direction), that is, the front direction of the corresponding pixel 9. In addition, in this example, the auxiliary lens 52RG brings the traveling direction of the red light from the main lens 51R close to the front direction of the pixel 9R, and brings the traveling direction of the green light from the main lens 51G close to the front direction of the pixel 9G. In addition, the auxiliary lens 52GB brings the traveling direction of the green light from the main lens 51G close to the front direction of the pixel 9G, and brings the traveling direction of the blue light from the main lens 51B close to the front direction of the pixel 9B.

In the example illustrated in FIG. 1, the auxiliary lens 52 is a condenser lens having a convex shape (for example, a semicircular shape) protruding toward the array of the plurality of main lenses 51, that is, in a direction (Z-axis negative direction) opposite to the front direction. The auxiliary lens 52 may have a refractive index higher than the refractive index of the base portion 50. Various known materials may be used. The refractive index of the auxiliary lens 52 may be the same as or different from the refractive index of the main lens 51. The material of the auxiliary lens 52 may be the same as or different from the material of the main lens 51.

In the plan view of the lens layer 5, a part of the auxiliary lens 52 may overlap a part of at least one main lens 51 of the corresponding adjacent main lenses 51. Thus, more light can be made incident on the auxiliary lens 52 as compared with a case where the auxiliary lens 52 and the main lens 51 do not overlap. In the example illustrated in FIG. 1, a part of the auxiliary lens 52RG overlaps a part of the main lens 51R, and another part of the auxiliary lens 52RG overlaps a part of the main lens 51G. A part of the auxiliary lens 52GB overlaps another part of the main lens 51G, and another part of the auxiliary lens 52GB overlaps a part of the main lens 51B.

In the plan view of the lens layer 5, the auxiliary lens 52 may be located at an edge portion of the pixel 9. In the example illustrated in FIG. 1, the auxiliary lens 52RG is located at an edge portion of the pixel 9R and at an edge portion of the pixel 9G. The auxiliary lens 52GB is located at an edge portion of the pixel 9G and at the edge portion of the pixel 9B.

Note that, in the example illustrated in FIG. 1, a portion formed of the same material as that of the auxiliary lens 52 extends along a surface (surface on the Z-axis positive direction side) of the lens layer 5. The portion covers the base portion 50, and the base portion 50 is not exposed on the surface of the lens layer 5.

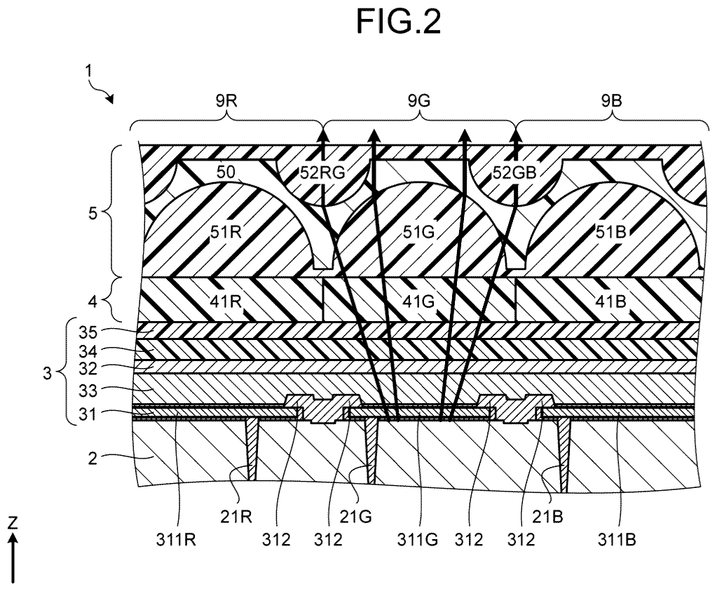

The light extraction efficiency is improved by the auxiliary lens 52. Description will be made with reference to FIGS. 2 to 4.

FIG. 2 is a view illustrating an example of the traveling direction of light. As schematically indicated by arrows, in the pixel 9G, green light out of light from the light emitting element layer 3 passes through the color filter 4G, and the traveling direction thereof is brought close to the front direction by the main lens 51G. At the edge portion of the pixel 9G, part of the green light having passed through the main lens 51G passes through the auxiliary lens 52RG, and the traveling direction thereof is further brought close to the front direction. In addition, another part of the green light having passed through the main lens 51G passes through the auxiliary lens 52GB, and the traveling direction thereof is further brought close to the front direction. Since not only light at a central portion of the pixel 9G but also light at the edge portion of the pixel 9G is extracted in the front direction of the pixel 9G, the light extraction efficiency is improved accordingly. Although not illustrated, the same applies to the pixel 9R and the pixel 9B.

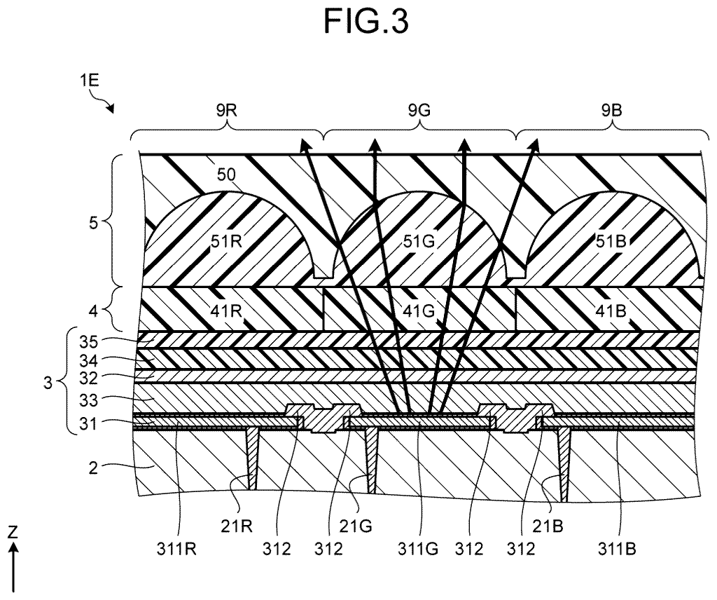

FIG. 3 is a view illustrating a comparative example. A display device 1E according to the comparative example is different from the display device 1 (FIG. 2) in that the auxiliary lens 52 is not included. Since the auxiliary lens 52 is not provided, light at an edge portion of the pixel 9G is not extracted in the front direction (Z-axis positive direction) of the pixel 9G as schematically indicated by arrows, and the light extraction efficiency decreases. Although not illustrated, the same applies to the pixel 9R and the pixel 9B.

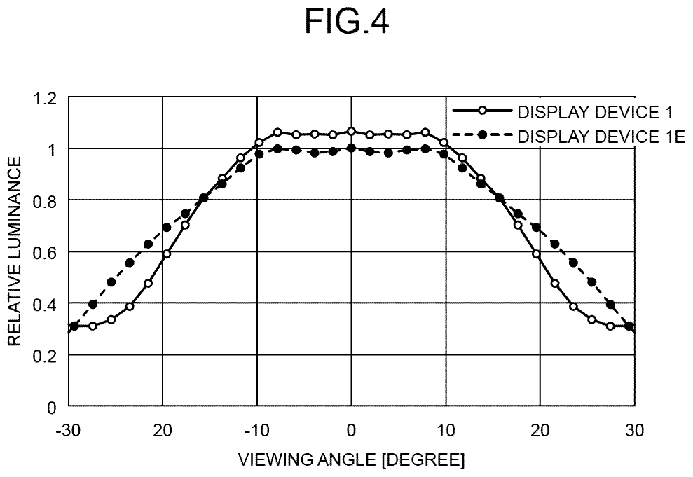

FIG. 4 is a view illustrating an example of the light extraction efficiency. A horizontal axis of a graph indicates a viewing angle (degree). A vertical axis of the graph represents relative luminance. The viewing angle is an angle with respect to the Z-axis direction, and zero degree corresponds to the front direction (Z-axis positive direction). The luminance in the front direction of the display device 1 according to the embodiment (FIG. 2) is larger than that of the display device 1E according to the comparative example (FIG. 3). It can be seen that the light extraction efficiency can be improved by the display device 1 including the auxiliary lens 52.

As described above, since the lens layer 5 includes not only the main lenses 51 but also the auxiliary lenses 52 in the display device 1 according to the embodiment, light in a portion between the main lenses 51 is also easily extracted in the front direction of the pixel 9. That is, not only the light at the central portion of the pixel 9 but also the light at the edge portion of the pixel 9 can be easily extracted in the front direction of the pixel 9. Therefore, it is possible to improve the light extraction efficiency and improve the light emission efficiency as described at the beginning. An effect of reducing power consumption by improving the efficiency can also be obtained.

In addition, in the display device 1 according to the embodiment, it is also possible to increase the amount of light emission in the light emitting element layer 3 by increasing the area (opening area) of a portion on the electrode 311 not covered with the electrode edge film 312. When the opening area is increased, light at the edge portion of the pixel 9 increases, but the light at this portion can also be extracted in the front direction. Since the amount of light emission is increased, for example, the maximum luminance of the display device 1 can be improved.

On the other hand, in the display device 1E according to the comparative example, light at the edge portion of the pixel 9 cannot be extracted in the front direction, and a loss due to leakage light increases even if the opening area is increased. In order to increase the amount of light emission without increasing the opening area, it is necessary to increase the amount of current per area flowing through the light emitting element layer 3. However, the amount of current is limited from the viewpoint of service life of the light emitting element or the like. Such a problem can also be addressed by the display device 1 according to the embodiment.

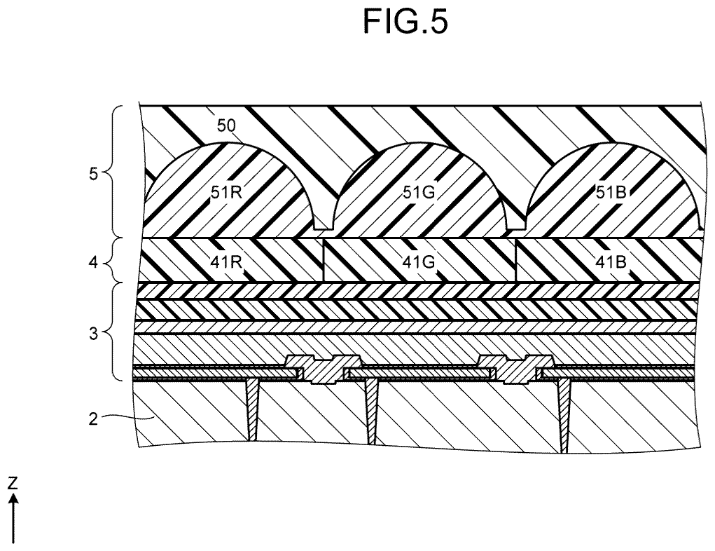

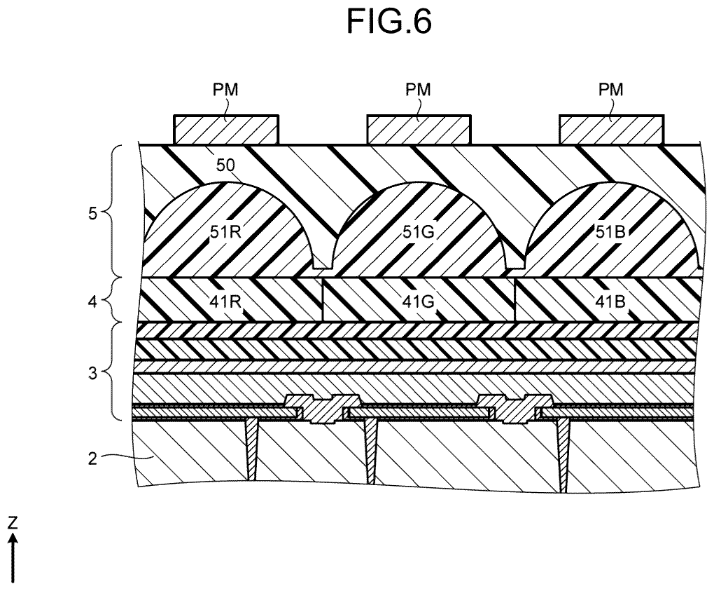

FIGS. 5 to 8 are views illustrating examples of a manufacturing method of the display device. In particular, formation of the auxiliary lens 52 will be described. First, as illustrated in FIG. 5, the light emitting element layer 3, the color filter layer 4, and the lens layer 5 in which the main lens 51 is embedded are sequentially formed on the base 2 using a known method. Thereafter, as illustrated in FIGS. 6 to 8, the auxiliary lens 52 embedded in the lens layer 5 is formed.

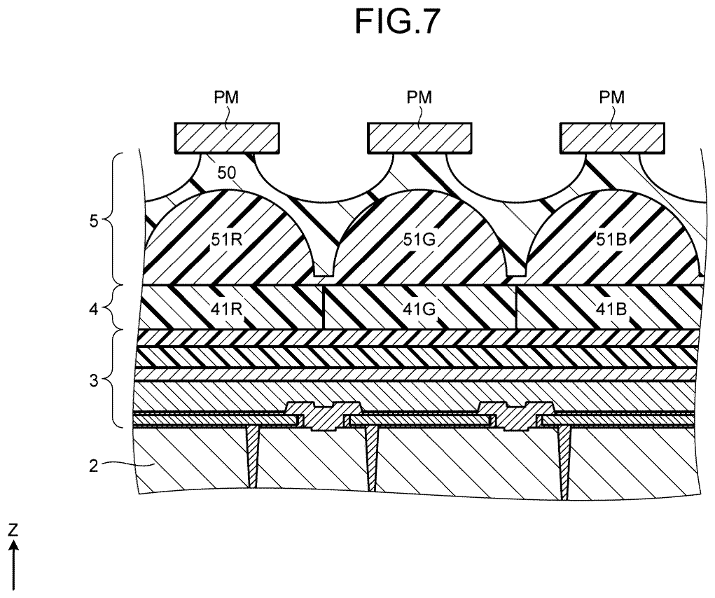

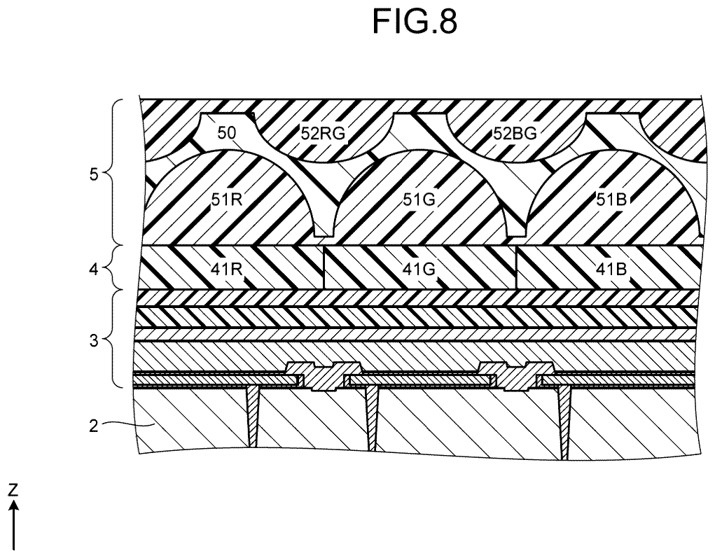

Specifically, as illustrated in FIG. 6, a photoresist material PM is arranged on the lens layer 5. The photoresist material PM is applied onto a part of the lens layer 5 so as to obtain a pattern of the auxiliary lens 52. As illustrated in FIG. 7, the lens layer 5 is processed by dry etching or the like. After the photoresist material PM is removed, the material of the auxiliary lens 52 is provided on the lens layer 5 as illustrated in FIG. 8. For example, the material of the auxiliary lens 52 is applied. In a case where the material is a resin, sealing with the resin may be performed. For example, the display device 1 including the auxiliary lens 52 can be manufactured in this manner.

Some examples of variations of configurations of the display device 1 will be described. Among the configurations described below, non-exclusive configurations may be arbitrarily combined.

### 2. Variations of Cross-Sectional Structure

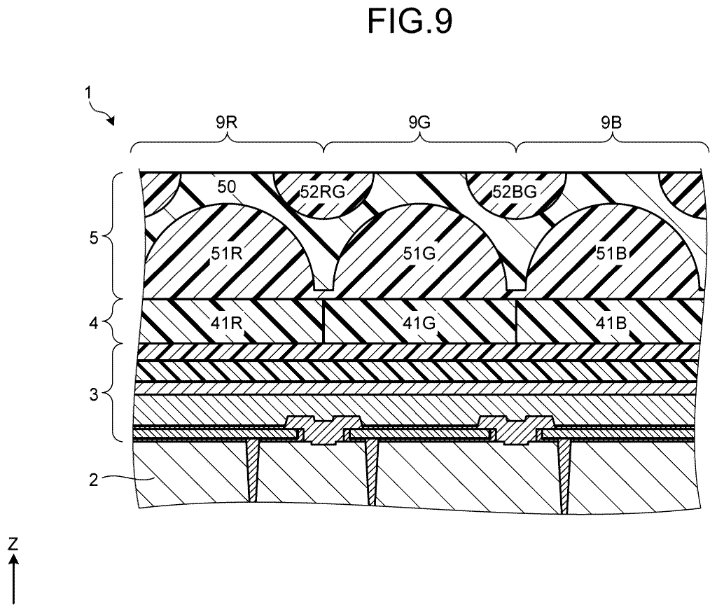

FIGS. 9 to 17 are views illustrating variations of a cross-sectional structure. Hereinafter, description will be made in order.

In an example illustrated in FIG. 9, the base portion 50 is exposed at a portion excluding auxiliary lens 52 on the surface (surface on the Z-axis positive direction side) of the lens layer 5. This configuration is obtained, for example, by removing a portion covering the base portion 50 in FIG. 1 described above by etching or the like.

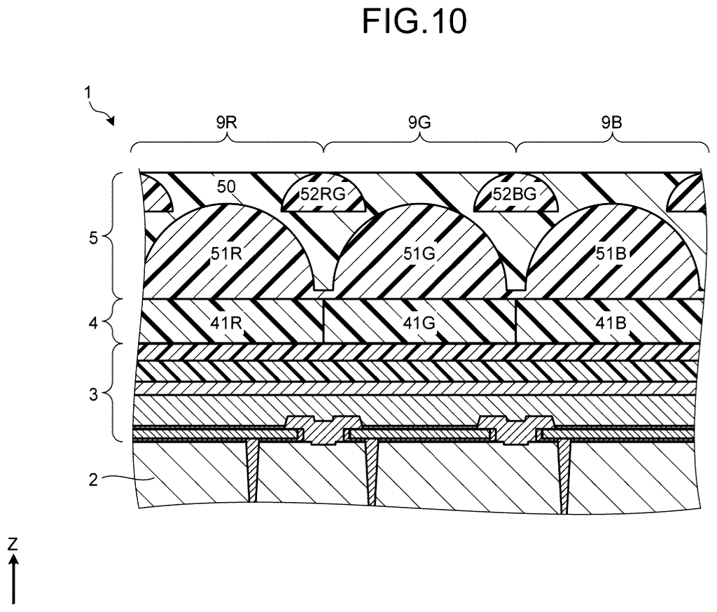

In an example illustrated in FIG. 10, the auxiliary lens 52 has a convex shape (for example, a semicircular shape) protruding in the direction (Z-axis positive direction) opposite to a direction toward the array of the plurality of main lenses 51.

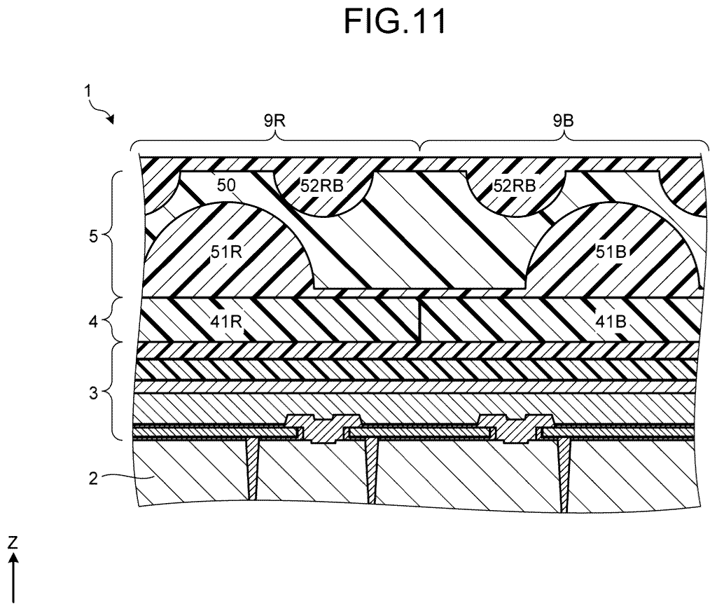

In an example illustrated in FIG. 11, when the lens layer 5 is viewed in plan view (viewed in the Z-axis direction), the two auxiliary lenses 52 are located between the adjacent main lenses 51. In this example, the pixel 9R and the pixel 9B are adjacent to each other, and the two auxiliary lenses 52RB are arranged side by side between the main lens 51 of the pixel 9R and the main lens 51B of the pixel 9B. Although not illustrated, three or more auxiliary lenses 52 may be arranged. Any number of the auxiliary lenses 52 according to design or the like can be provided between the adjacent main lenses 51.

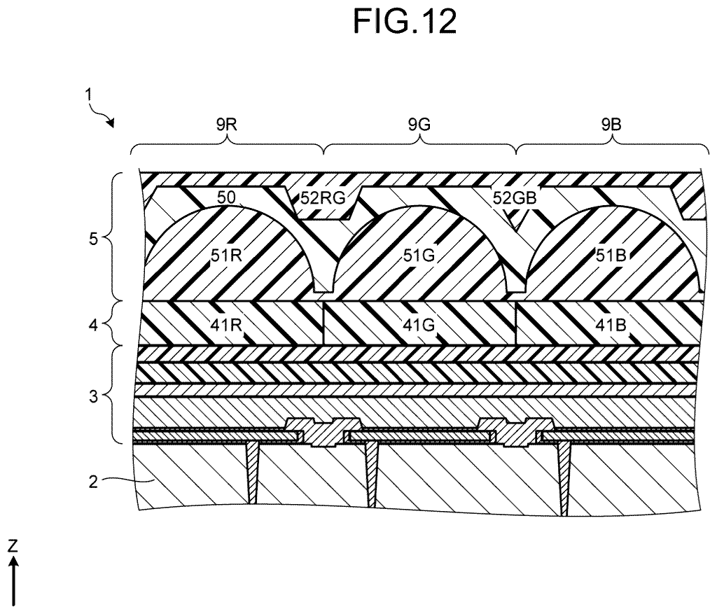

In an example illustrated in FIG. 12, the convex shape of the auxiliary lens 52 includes a trapezoidal shape and a triangular shape. In this example, the auxiliary lens 52RG has the trapezoidal shape, and the auxiliary lens 52GB has the triangular shape.

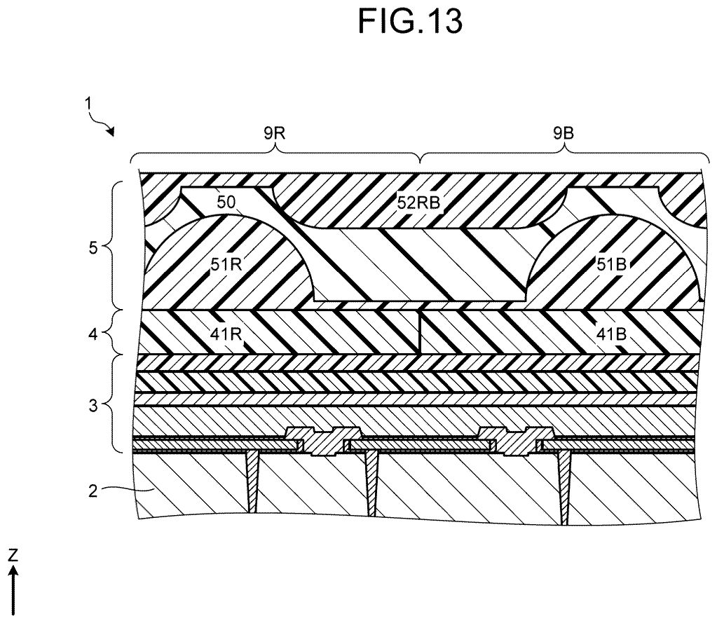

In an example illustrated in FIG. 13, the auxiliary lens 52 has a flat portion at a bottom portion (a portion on the negative Z-direction side) thereof. In this example, a bottom surface of the auxiliary lens 52RB has a flat surface.

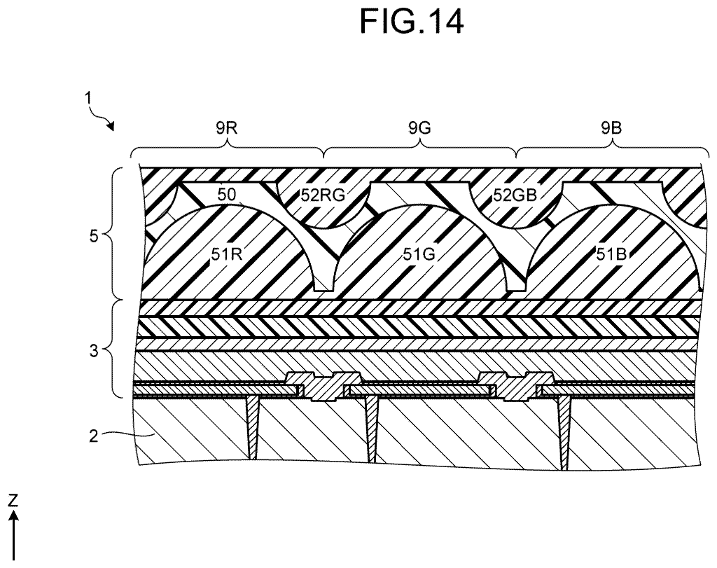

In an example illustrated in FIG. 14, the display device 1 does not include the color filter layer 4. In this example, the lens layer 5 is provided on the light emitting element layer 3. The light emitting element layer 3 is configured to emit red light in the pixel 9R, emit green light in the pixel 9G, and emit blue light in the pixel 9B.

In an example illustrated in FIG. 15, the lens layer 5 further includes a plurality of main lenses 51-2 (corresponding to reference sign 51-2R and the like in the drawing). The plurality of main lenses 51-2 are provided on a side opposite to the auxiliary lens 52 across the array of the plurality of main lenses 51, and are a plurality of second main lenses corresponding to the plurality of main lenses 51. A material of the main lens 51-2 may be the same as the material of the main lens 51.

The main lens 51-2 of the pixel 9R is referred to as the main lens 51-2R in the drawing. The main lens 51-2 of the pixel 9G is referred to as a main lens 51-2G in the drawing. The main lens 51-2 of the pixel 9B is referred to as a main lens 51-2B in the drawing.

In this example, the main lens 51-2R brings the traveling direction of red light from the main lens 51R, the auxiliary lens 52RG, and the like close to the front direction (Z-axis positive direction) of the pixel 9R. The main lens 51-2G brings the traveling direction of green light from the main lens 51G, the auxiliary lens 52RG, and the auxiliary lens 52GB close to the front direction of the pixel 9G. The main lens 51-2B brings the traveling direction of blue light from the main lens 51B, the auxiliary lens 52GB, and the like close to the front direction of the pixel 9B. Thus, the light extraction efficiency can be further improved.

In an example illustrated in FIG. 16, the lens layer 5 further includes one or more auxiliary lenses 52-2 (corresponding to reference sign 52-2RG and the like in the drawing). The auxiliary lens 52-2 is provided on a side opposite to the auxiliary lens 52 across an array of the main lenses 51-2, and is a second auxiliary lens corresponding to the auxiliary lens 52. A material of the auxiliary lens 52-2 may be the same as the material of the auxiliary lens 52.

When the lens layer 5 is viewed in plan view (viewed in the Z-axis direction), the auxiliary lens 52-2 is located between adjacent main lenses 51-2 among the plurality of main lenses 51-2. The auxiliary lens 52-2 located between the main lens 51-2R and the main lens 51-2G is referred to as the auxiliary lens 52-2RG in the drawing. The auxiliary lens 52-2 located between the main lens 51-2G and the main lens 51-2B is referred to as an auxiliary lens 52-2GB in the drawing.

In addition, in this example, the auxiliary lens 52-2RG brings the traveling direction of the red light from the main lens 51-2R close to the front direction of the pixel 9R, and brings the traveling direction of the green light from the main lens 51-2G close to the front direction of the pixel 9G. In addition, the auxiliary lens 52-2GB brings the traveling direction of the green light from the main lens 51-2G close to the front direction of the pixel 9G, and brings the blue light from the main lens 51-2B close to the front direction of the pixel 9B. Thus, the light extraction efficiency can be further improved.

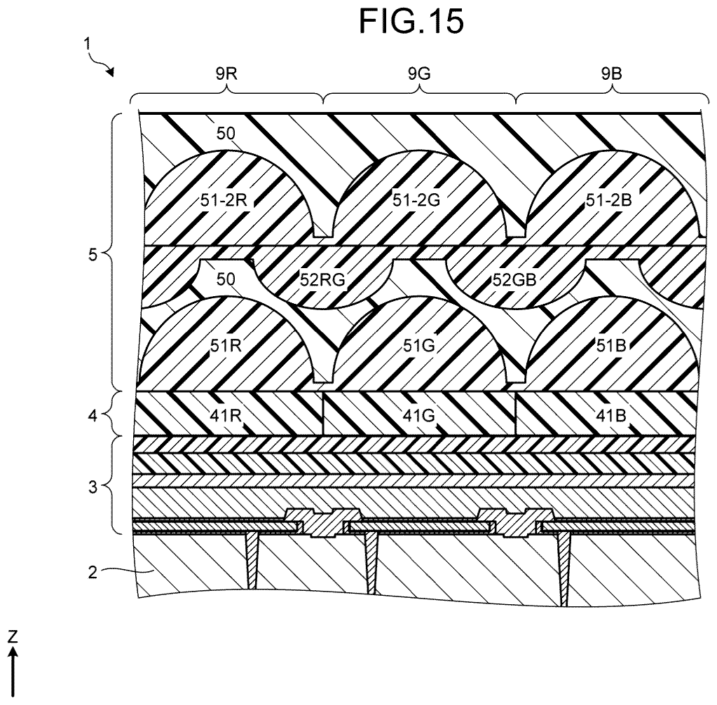

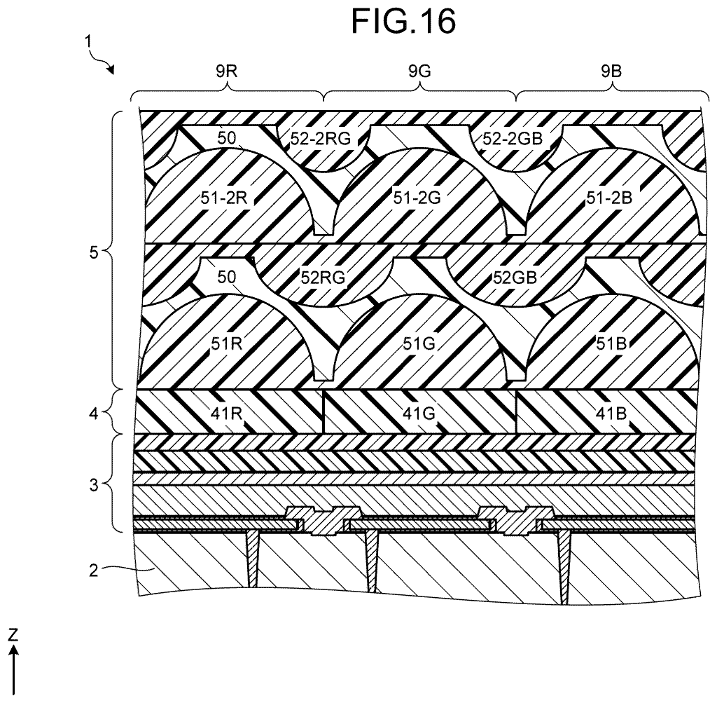

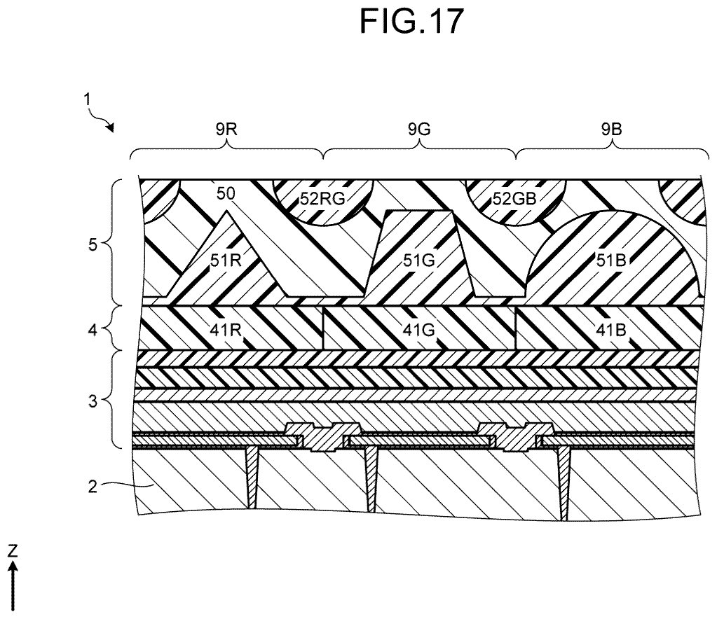

In an example illustrated in FIG. 17, the convex shape of the main lens 51 includes a triangular shape and a trapezoidal shape. In this example, the main lens 51R has the triangular shape, and the main lens 51G has the trapezoidal shape.

### 3. Variations of Planar Layout

FIGS. 18 to 26 are views illustrating variations of a planar layout. A planar layout of a part of the lens layer 5 when viewed in the Z-axis negative direction is schematically illustrated. Hereinafter, description will be made in order.

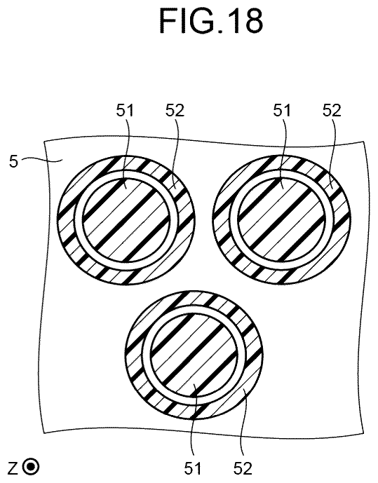

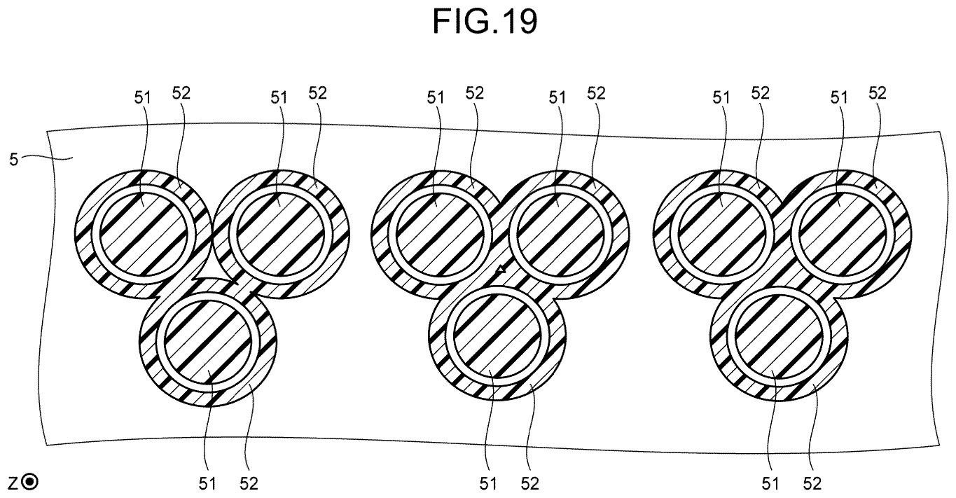

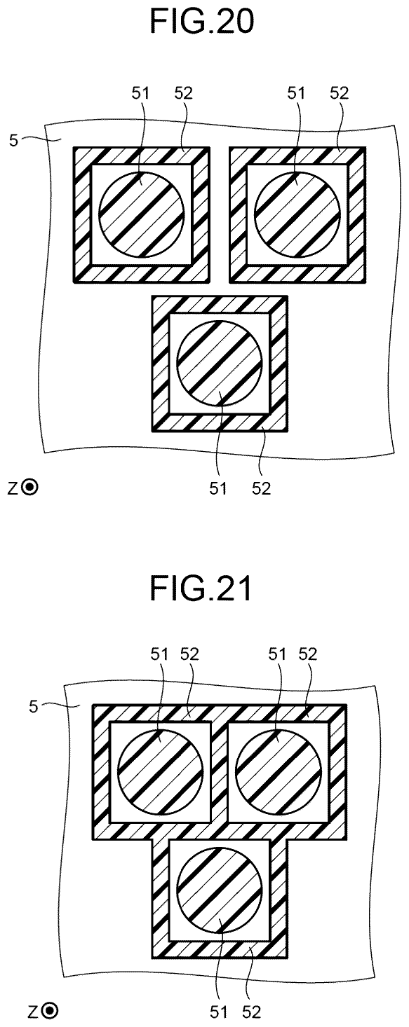

In examples illustrated in FIGS. 18 to 21, a pixel arrangement is a delta arrangement, and the plurality of main lenses 51 also form a delta arrangement. The auxiliary lens 52 may have an annular shape surrounding the main lens 51. The annular shape of the auxiliary lens 52 may be a circular annular shape as illustrated in FIGS. 18 and 19 or a rectangular annular shape as illustrated in FIGS. 20 and 21. The auxiliary lenses 52 corresponding to the adjacent main lenses 51 may be spaced apart from each other as illustrated in FIGS. 18 and 20, or may be connected as illustrated in FIGS. 19 and 21.

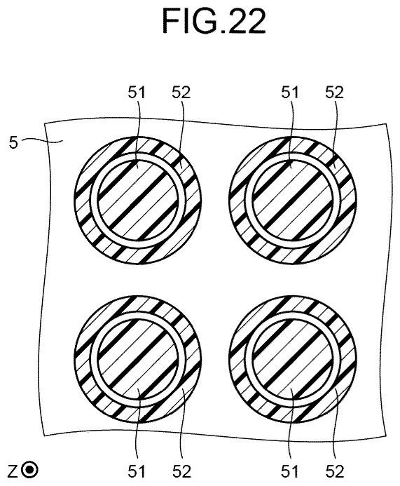

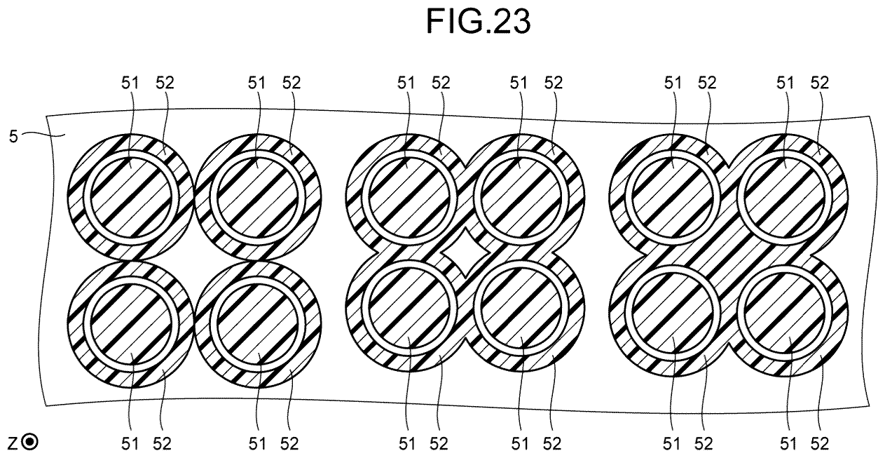

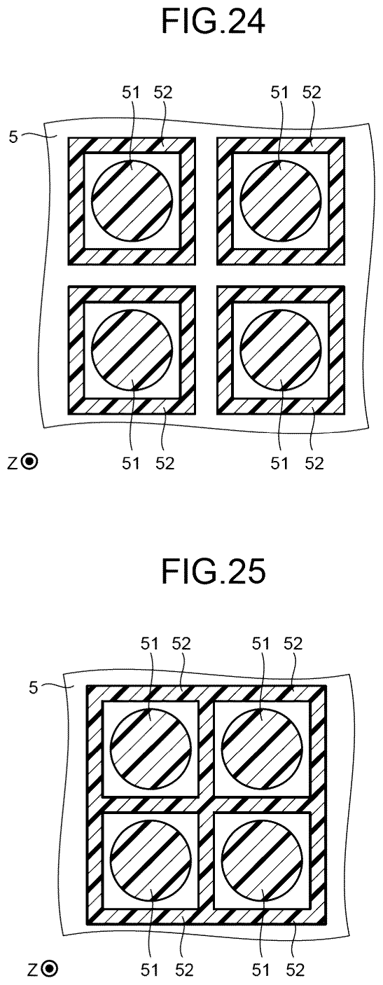

In examples illustrated in FIGS. 22 to 25, a pixel arrangement is a square arrangement, and the plurality of main lenses 51 also form a square arrangement. Similarly to the above, the auxiliary lens 52 may have an annular shape surrounding the main lens 51. The annular shape of the auxiliary lens 52 may be a circular annular shape as illustrated in FIGS. 22 and 23 or a rectangular annular shape as illustrated in FIGS. 24 and 25. The auxiliary lenses 52 corresponding to the adjacent main lenses 51 may be spaced apart from each other as illustrated in FIGS. 22 and 24 or may be connected as illustrated in FIGS. 23 and 25.

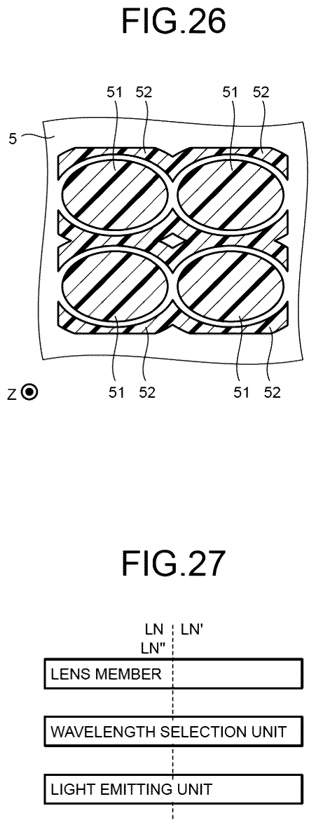

The present invention is not limited to the above examples, and various planar layouts according to layout restrictions and the like may be adopted. For example, the auxiliary lens 52 does not need to surround the entire periphery of the main lens 51. The auxiliary lens 52 may have various planar shapes corresponding to a planar shape of the main lens 51. In an example illustrated in FIG. 26, the main lens 51 has an elliptical shape. The auxiliary lens 52 is provided between the main lenses 51 adjacent in the shorter-axis direction of the ellipse, but is not provided between the main lenses 51 adjacent in the longer-axis direction of the ellipse.

In addition, as described above, a part of the auxiliary lens 52 may overlap a part of at least one main lens 51 of the corresponding adjacent main lenses 51.

### 4. Example of Effects

The technology described above is specified as follows, for example. One of the disclosed technology is the display device 1. As described with reference to FIGS. 1 and 9 to 26 and the like, the display device 1 includes the light emitting element layer 3 provided on the base 2 and the lens layer 5 provided on the side opposite to the base 2 across the light emitting element layer 3. The lens layer 5 includes the plurality of main lenses 51 arranged in the array in the plane direction (plane direction orthogonal to the Z-axis direction) of the lens layer 5, and the auxiliary lenses 52 provided on the side opposite to the light emitting element layer 3 across the array of the plurality of main lenses 51. When the lens layer 5 is viewed in plan view (viewed in the Z-axis direction), the auxiliary lens 52 is located between adjacent main lenses 51 among the plurality of main lenses 51.

According to the above display device 1, since the lens layer 5 includes not only the main lenses 51 but also the auxiliary lenses 52, light in a portion between the main lenses 51 is also easily extracted in the front direction of the pixel 9. Therefore, the light extraction efficiency can be improved.

As described with reference to FIGS. 1 and 2 and the like, the main lens 51 may bring the traveling direction of the light from the light emitting element layer 3 close to the front direction (Z-axis positive direction) of the display device 1, and the auxiliary lens 52 may bring the traveling direction of the light from the main lens 51 close to the front direction. The auxiliary lens 52 may have the refractive index higher than a refractive index of a portion (the base portion 50) between the auxiliary lens 52 and the main lens 51 in the lens layer 5. For example, since the main lens 51 and the auxiliary lens 52 having such a configuration are used in combination, the light extraction efficiency can be improved as compared with the case of using only the main lens 51.

As described with reference to FIGS. 1, 2, 9 to 17, and the like, the main lens 51 may be provided for each of the pixels 9, and the auxiliary lens 52 may be located at the edge portion of the pixel 9 when the lens layer 5 is viewed in plan view (viewed in the Z-axis direction). Thus, not only the light at the central portion of the pixel 9 but also the light at the edge portion of the pixel 9 can be extracted in the front direction of the pixel 9.

As described with reference to FIGS. 1, 2, 9 to 17, and the like, when the lens layer 5 is viewed in plan view (viewed in the Z-axis direction), a part of the auxiliary lens 52 may overlap a part of at least one main lens 51 of the corresponding adjacent main lenses 51. Thus, for example, more light can be made incident on the auxiliary lens 52 as compared with a case where the auxiliary lens 52 and the main lens 51 do not overlap.

As described with reference to FIGS. 1, 2, 9, 10, 12 to 17, and the like, one auxiliary lens 52 may be located between the adjacent main lenses 51 when the lens layer 5 is viewed in plan view (viewed in the Z-axis direction). Alternatively, as described with reference to FIG. 11 and the like, two or more auxiliary lenses 52 may be located between the adjacent main lenses 51 when the lens layer 5 is viewed in plan view (viewed in the Z-axis direction). Any number of the auxiliary lenses 52 according to design or the like can be provided between the adjacent main lenses 51.

As described with reference to FIGS. 1, 2, 9, 11 to 17, and the like, the auxiliary lens 52 may have the convex shape protruding toward the array of the plurality of main lenses 51 (in the negative Z-axis direction). The convex shape of the auxiliary lens 52 may include at least one of a semicircular shape, a triangular shape, and a trapezoidal shape. As described with reference to FIGS. 18 to 25 and the like, the auxiliary lens 52 may have the annular shape surrounding the main lens 51 when the lens layer 5 is viewed in plan view (viewed in the Z-axis direction). The annular shape of the auxiliary lens 52 may include at least one of a circular annular shape and a rectangular annular shape. For example, the auxiliary lens 52 having various shapes can be used.

As described with reference to FIG. 15 and the like, the lens layer 5 may further include the plurality of main lenses 51-2 (second main lenses) that are provided on the side opposite to the auxiliary lenses 52 across the array of the plurality of main lenses 51 and correspond to the plurality of main lenses 51. In this case, the lens layer 5 may further include the auxiliary lens 52-2 (second auxiliary lens) provided on the side opposite to the auxiliary lens 52 across the array of the plurality of main lenses 51-2 as described with reference to FIG. 16 and the like. Thus, the light extraction efficiency can be further improved.

As described with reference to FIGS. 2, 9 to 13, 15 to 17, and the like, the display device 1 may further include the color filter layer 4 provided between the light emitting element layer 3 and the lens layer 5. Also in such a configuration, the light extraction efficiency can be improved.

### 5. Other Modifications

### First Modification

Other modifications will be described. First, with reference to FIGS. 27 to 33, a modification related to a relationship among a normal line LN passing through a center of the pixel 9 (hereinafter, also referred to as a “subpixel”), a normal line LN′ passing through a center of the main lens 51 (hereinafter, also referred to as a “lens member”), and a normal line LN″ passing through a center of the color filter 4R or the like (hereinafter, also referred to as a “wavelength selection unit”) will be described. FIGS. 27 to 33 are conceptual views for describing the relationship among the normal line LN passing through the center of the subpixel, the normal line LN′ passing through the center of the lens member, and the normal line LN″ passing through the center of the wavelength selection unit. Note that the center of the subpixel is referred to as a center of a light emitting unit in the following description.

A size of the wavelength selection unit may be appropriately changed in accordance with light emitted from the subpixel. A light absorbing layer (black matrix layer) may be provided between the wavelength selection units of adjacent subpixels. In this case, a size of the light absorbing layer may be appropriately changed in accordance with the light emitted from the subpixel. In addition, the size of the wavelength selection unit may be appropriately changed according to a distance (offset amount) d0 between the normal line passing through the center of the subpixel and the normal line passing through the center of the wavelength selection unit. A planar shape of the wavelength selection unit may be the same as, similar to, or different from a planar shape of the lens member.

For example, as illustrated in FIG. 27, the normal line LN passing through the center of the light emitting unit, the normal line LN″ passing through the center of the wavelength selection unit, and the normal line LN′ passing through the center of the lens member may coincide with each other. In other words, a distance (offset amount) D₀ between the normal line passing through the center of the light emitting unit and the normal line passing through the center of the lens member and the distance (offset amount) d₀ between the normal line passing through the center of the light emitting unit and the normal line passing through the center of the wavelength selection unit can be equally set to 0 (zero).

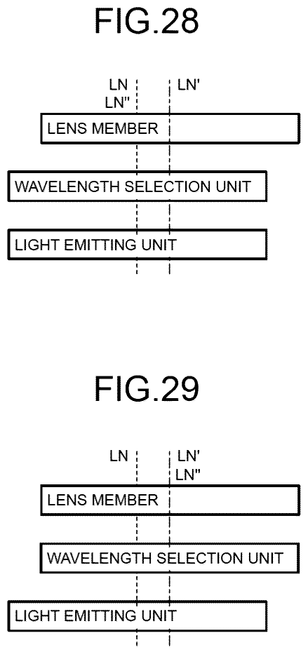

As illustrated in FIG. 28, the normal line LN passing through the center of the light emitting unit and the normal line LN″ passing through the center of the wavelength selection unit may coincide with each other, but the normal line LN passing through the center of the light emitting unit and the normal line LN″ passing through the center of the wavelength selection unit may not coincide with the normal line LN′ passing through the center of the lens member. In other words, D₀≠d₀=0 may be established.

As illustrated in FIG. 29, the normal line LN passing through the center of the light emitting unit may not coincide with the normal line LN″ passing through the center of the wavelength selection unit and the normal line LN′ passing through the center of the lens member, and the normal line LN″ passing through the center of the wavelength selection unit may coincide with the normal line LN′ passing through the center of the lens member. In other words, D₀=d₀>0 may be established.

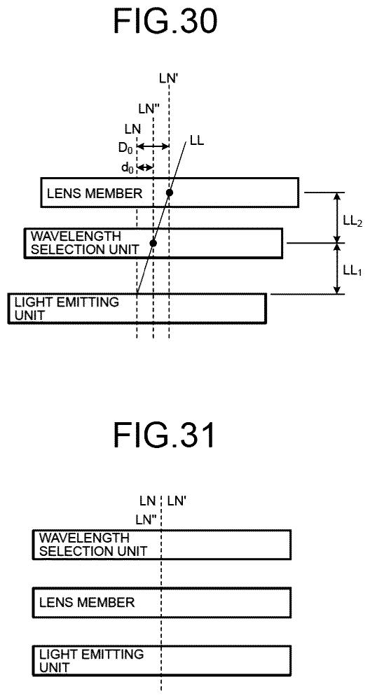

As illustrated in FIG. 30, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center (illustrated as a black circle) of the wavelength selection unit is preferably located on a straight line LL connecting the center of the light emitting unit and the center (illustrated as a black circle) of the lens member. Specifically, when a distance from the center of the light emitting unit to the center of the wavelength selection unit is LL₁ in a thickness direction and a distance from the center of the wavelength selection unit to the center of the lens member is LL₂ in the thickness direction, D₀>d₀>0 is established, and it is preferable to satisfy d₀:D₀=LL₁:(LL₁+LL₂) in consideration of manufacturing variations.

A stacking relationship between the wavelength selection unit and the lens member may be interchanged. In this case, for example, as illustrated in FIG. 31, the normal line LN passing through the center of the light emitting unit, the normal line LN″ passing through the center of the wavelength selection unit, and the normal line LN′ passing through the center of the lens member may coincide with each other. In other words, D₀=d₀=0 may be established.

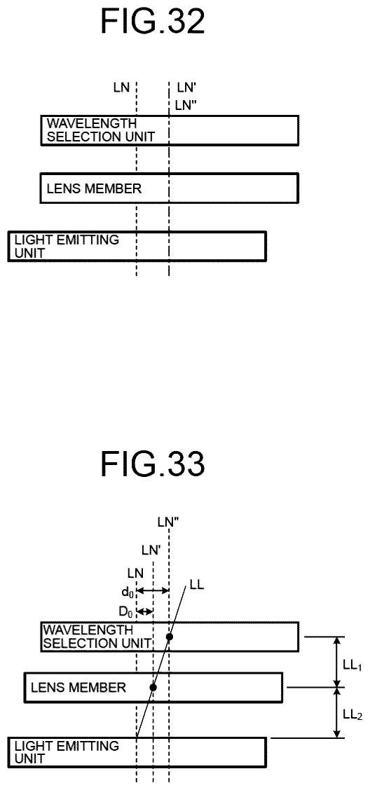

As illustrated in FIG. 32, the normal line LN passing through the center of the light emitting unit may not coincide with the normal line LN″ passing through the center of the wavelength selection unit and the normal line LN′ passing through the center of the lens member, and the normal line LN″ passing through the center of the wavelength selection unit may coincide with the normal line LN′ passing through the center of the lens member. In other words, D₀=d₀>0 may be established.

As illustrated in FIG. 33, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit is preferably located on a straight line LL connecting the center of the light emitting unit and the center of the lens member. Specifically, when a distance from the center of the light emitting unit to the center (illustrated as a black circle) of the wavelength selection unit is LL₁ in a thickness direction and a distance from the center of the wavelength selection unit to the center (illustrated as a black circle) of the lens member is LL₂ in the thickness direction, d₀>D₀>0 is established, and it is preferable to satisfy D₀: d₀=LL₂: (LL₁+LL₂) in consideration of manufacturing variations.

### Second Modification

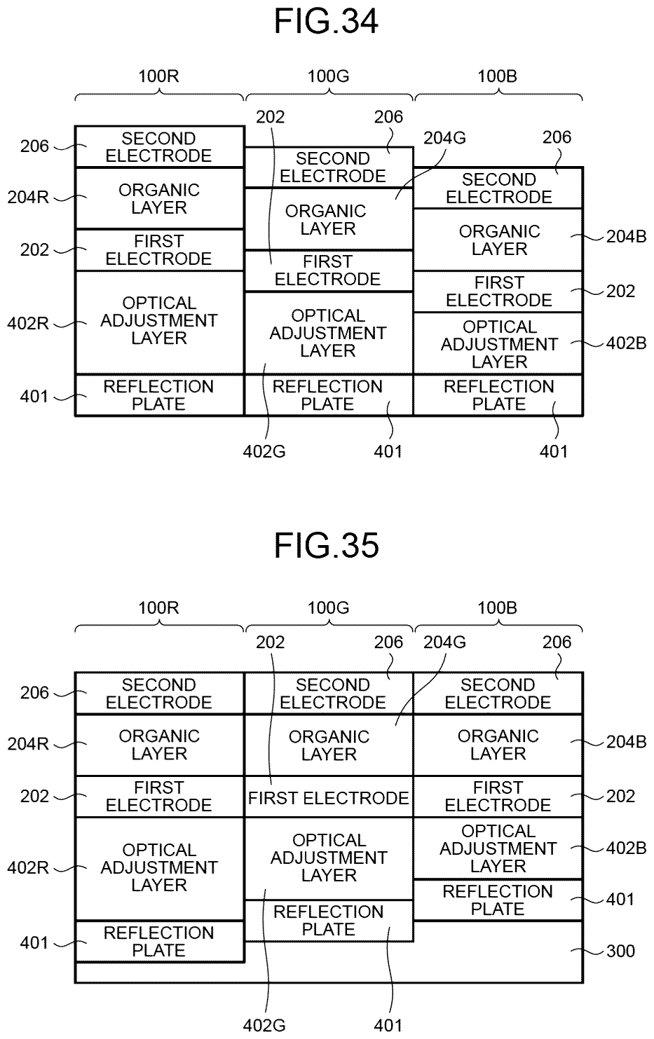

A subpixel may have a resonator structure that causes light generated in the light emitting element layer 3 to resonate. Description will be made with reference to FIGS. 34 to 40. FIGS. 34 to 40 are schematic cross-sectional views for describing first to seventh examples of a resonance structure.

Hereinafter, the pixel 9R, the pixel 9B, and the pixel 9B described above will be described as examples of the subpixel. These pixels are referred to and illustrated as a subpixel 100R, a subpixel 100G, and a subpixel 100B, respectively, in FIGS. 46 to 52. The light emitting element layer 3 is an organic material layer of an OLED, and is referred to and illustrated as an organic layer 204R, an organic layer 204G, and an organic layer 204B. The electrode layer 31 described above is referred to and illustrated as a first electrode 202. The electrode layer 32 described above is referred to and illustrated as a second electrode 206. The base 2 described above is referred to and illustrated as a substrate 300 in the drawing.

### (Resonator Structure: First Example)

FIG. 34 is a schematic cross-sectional view for describing the first example of the resonator structure. In the first example, the first electrode (for example, an anode electrode) 202 is formed with a common film thickness in each subpixel. The same applies to the second electrode (for example, a cathode electrode) 206.

As illustrated in FIG. 34, a reflection plate 401 is disposed below the first electrode 202 of the subpixel 100 with an optical adjustment layer 402 interposed therebetween. A resonator structure that resonates light generated by the organic layer (specifically, a light emitting layer) 204 is formed between the reflection plate 401 and the second electrode 206.

The reflection plate 401 is formed with a common film thickness in each of the subpixels 100. A film thickness of the optical adjustment layer 402 is different depending on a color to be displayed by the subpixel 100. Since the optical adjustment layers 402R, 402G, and 402B have different film thicknesses, it is possible to set an optical distance for causing optimum resonance for a wavelength of light according to a color to be displayed.

In the example illustrated in FIG. 34, upper surfaces of the reflection plates 401 in the subpixels 100R, 100G, and 100B are arranged to be aligned. As described above, since the film thickness of the optical adjustment layer 402 is different depending on a color to be displayed by the subpixel 100, positions of the upper surfaces of the second electrode 206 vary depending on types of the subpixels 100R, 100G, and 100B.

The reflection plate 401 can be formed using, for example, metal such as aluminum (Al), silver (Ag), or copper (Cu), or an alloy containing these as main components.

The optical adjustment layer 402 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a laminated film of a plurality of materials. In addition, the number of laminated layers may be different depending on the type of the subpixel 100.

The first electrode 202 can be formed using, for example, a transparent conductive material such as indium tin oxide (ITO), indium zinc oxide (IZO), or zinc oxide (ZnO).

The second electrode 206 preferably functions as a semi-transmissive reflection film. The second electrode 206 can be formed using magnesium (Mg), silver (Ag), a magnesium-silver alloy (MgAg) containing these as main components, an alloy containing an alkali metal or an alkaline earth metal, or the like.

### (Resonator Structure: Second Example)

FIG. 35 is a schematic cross-sectional view for describing the second example of the resonator structure. Also in the second example, each of the first electrode 202 and the second electrode 206 is formed with a common film thickness in each of the subpixels 100.

Further, also in the second example, the reflection plate 401 is disposed below the first electrode 202 of the subpixel 100 with the optical adjustment layer 402 interposed therebetween. A resonator structure that resonates light generated by the organic layer 204 is formed between the reflection plate 401 and the second electrode 206. As in the first example, the reflection plate 401 is formed with a common film thickness in each of the subpixels 100, and the film thickness of the optical adjustment layer 402 is different depending on a color to be displayed by the subpixel 100.

In the first example illustrated in FIG. 34, the upper surfaces of the reflection plates 401 in the subpixels 100R, 100G, and 100B are arranged to be aligned, and the positions of the upper surfaces of the second electrodes 206 vary depending on types of the subpixels 100R, 100G, and 100B.

On the other hand, in the second example illustrated in FIG. 35, upper surfaces of the second electrodes 206 are arranged to be aligned in the subpixels 100R, 100G, and 100B. In order to align the upper surfaces of the second electrodes 206, upper surfaces of the reflection plates 401 in the subpixels 100R, 100G, and 100B are arranged differently depending on types of the subpixels 100R, 100G, and 100B. Therefore, lower surfaces of the reflection plates 401 form a stepped shape depending on the types of the subpixels 100R, 100G, and 100B.

Materials and the like constituting the reflection plate 401, the optical adjustment layer 402, the first electrode 202, and the second electrode 206 are similar to the content described in the first example, and thus the description thereof will be omitted.

### (Resonator Structure: Third Example)

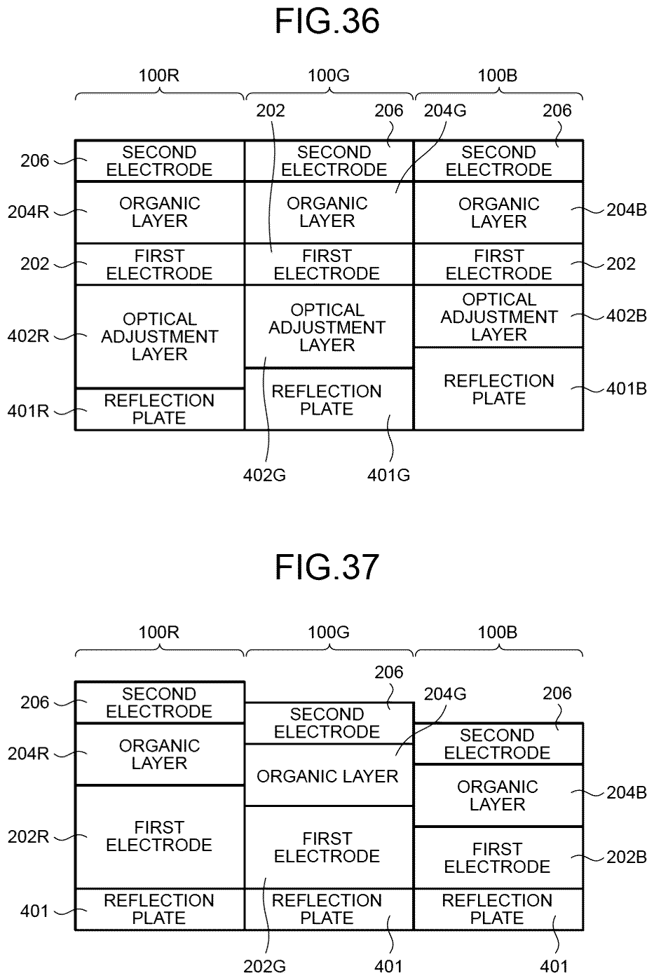

FIG. 36 is a schematic cross-sectional view for describing the third example of the resonator structure. Also in the third example, each of the first electrode 202 and the second electrode 206 is formed with a common film thickness in each of the subpixels 100.

Further, also in the third example, the reflection plate 401 is disposed below the first electrode 202 of the subpixel 100 with the optical adjustment layer 402 interposed therebetween. A resonator structure that resonates light generated by the organic layer 204 is formed between the reflection plate 401 and the second electrode 206. As in the first example and the second example, a film thickness of the optical adjustment layer 402 is different depending on a color to be displayed by the subpixel 100. Further, positions of upper surfaces of the second electrodes 206 are arranged to be aligned in the subpixels 100R, 100G, and 100B, which is similar to the second example.

In the second example illustrated in FIG. 35, the lower surfaces of the reflection plates 401 form the stepped shape depending on the types of the subpixels 100R, 100G, and 100B in order to align the upper surfaces of the second electrodes 206.

On the other hand, in the third example illustrated in FIG. 36, film thicknesses of the reflection plates 401 are set to be different depending on types of the subpixels 100R, 100G, and 100B. More specifically, the film thickness is set so as to align lower surfaces of the reflection plates 401R, 401G, and 401B.

Materials and the like constituting the reflection plate 401, the optical adjustment layer 402, the first electrode 202, and the second electrode 206 are similar to the content described in the first example, and thus the description thereof will be omitted.

### (Resonator Structure: Fourth Example)

FIG. 37 is a schematic cross-sectional view for describing the fourth example of the resonator structure.

In the first example illustrated in FIG. 34, each of the first electrodes 202 and each of the second electrode 206 in the subpixels 100 is formed with a common film thickness. Further, the reflection plate 401 is disposed below the first electrode 202 of the subpixel 100 with the optical adjustment layer 402 interposed therebetween.

On the other hand, in the fourth example illustrated in FIG. 37, the optical adjustment layer 402 is omitted, and the film thicknesses of the first electrodes 202 are set to be different depending on types of the subpixels 100R, 100G, and 100B.

The reflection plate 401 is formed with a common film thickness in each of the subpixels 100. The film thickness of the first electrode 202 is different depending on a color to be displayed by the subpixel 100. Since the first electrodes 202R, 202G, and 202B have different film thicknesses, it is possible to set an optical distance for causing optimum resonance for a wavelength of light according to a color to be displayed.

Materials and the like constituting the reflection plate 401, the first electrode 202, and the second electrode 206 are similar to the content described in the first example, and thus the description thereof will be omitted.

### (Resonator Structure: Fifth Example)

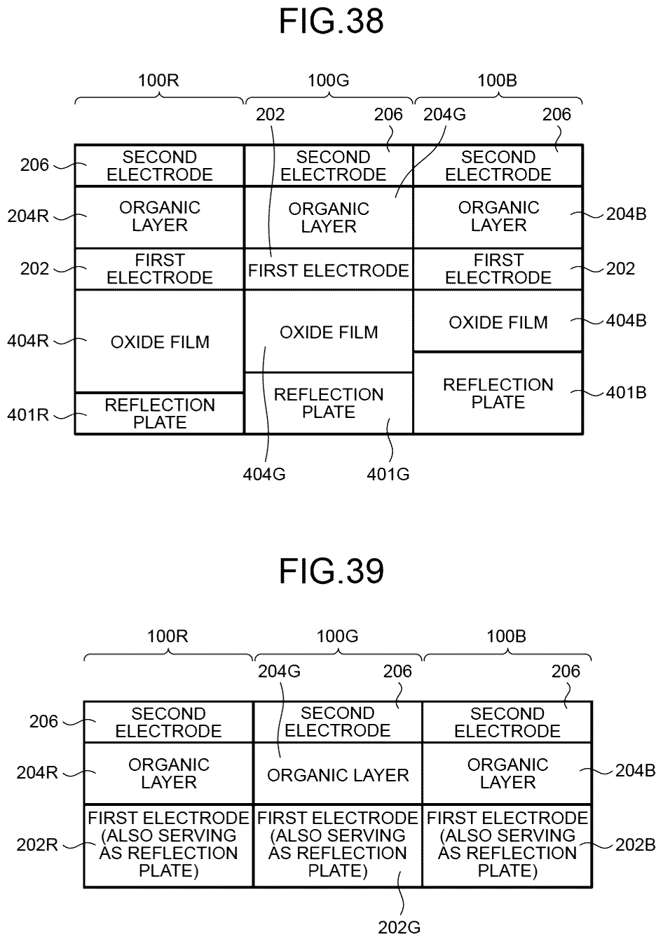

FIG. 38 is a schematic cross-sectional view for describing the fifth example of the resonator structure.

In the first example illustrated in FIG. 34, each of the first electrode 202 and the second electrode 206 is formed with a common film thickness in each of the subpixels 100. Further, the reflection plate 401 is disposed below the first electrode 202 of the subpixel 100 with the optical adjustment layer 402 interposed therebetween.

On the other hand, in the fifth example illustrated in FIG. 38, the optical adjustment layer 402 is omitted, and instead, an oxide film 404 is formed on a surface of the reflection plate 401. Film thicknesses of the oxide film 404 are set to be different depending on types of the subpixels 100R, 100G, and 100B.

The film thickness of the oxide film 404 is different depending on a color to be displayed by the subpixel 100. Since the oxide films 404R, 404G, and 404B have different film thicknesses, it is possible to set an optical distance for causing optimum resonance for a wavelength of light according to a color to be displayed.

The oxide film 404 is a film obtained by oxidizing the surface of the reflection plate 401, and is made of, for example, aluminum oxide, tantalum oxide, titanium oxide, magnesium oxide, zirconium oxide, or the like. The oxide film 404 functions as an insulating film for adjusting an optical path length (optical distance) between the reflection plate 401 and the second electrode 206.

The oxide films 404 having different film thicknesses depending on the types of the subpixels 100R, 100G, and 100B can be formed, for example, as follows.

First, a container is filled with an electrolytic solution, and a substrate on which the reflection plate 401 is formed is immersed in the electrolytic solution. In addition, an electrode is arranged so as to face the reflection plate 401.

Further, a positive voltage is applied to the reflection plate 401 with the electrode as a reference to anodize the reflection plate 401. A film thickness of an oxide film due to the anodization is proportional to a voltage value with respect to the electrode. Therefore, the anodization is performed in a state where voltages corresponding to the types of the subpixels 100R, 100G, and 100B are applied to the reflection plates 401R, 401G, and 401B, respectively. As a result, the oxide films 404 having different film thicknesses can be collectively formed.

Materials and the like constituting the reflection plate 401, the first electrode 202, and the second electrode 206 are similar to the content described in the first example, and thus the description thereof will be omitted.

### (Resonator Structure: Sixth Example)

FIG. 39 is a schematic cross-sectional view for describing the sixth example of the resonator structure. In the sixth example, the subpixel 100 is configured by stacking the first electrode 202, the organic layer 204, and the second electrode 206. However, in the sixth example, the first electrode 202 is formed to have both functions of an electrode and a reflection plate. The first electrodes (also serving as reflection plates) 202 are made of materials having optical constants selected depending on the types of the subpixels 100R, 100G, and 100B. Since phase shifts by the first electrodes (also serving as the reflection plates) 202 are different, it is possible to set an optical distance for causing optimum resonance for a wavelength of light according to a color to be displayed.

The first electrode (also serving as the reflection plate) 202 can be made of single metal such as aluminum (Al), silver (Ag), gold (Au), or copper (Cu), or an alloy containing these as main components. For example, the first electrode (also serving as the reflection plate) 202R of the subpixel 100R may be made of copper (Cu), and the first electrode (also serving as the reflection plate) 202G of the subpixel 100G and the first electrode (also serving as the reflection plate) 202B of the subpixel 100B may be made of aluminum.

A material and the like constituting the second electrode 206 are similar to the content described in the first example, and thus the description thereof will be omitted.

### (Resonator Structure: Seventh Example)

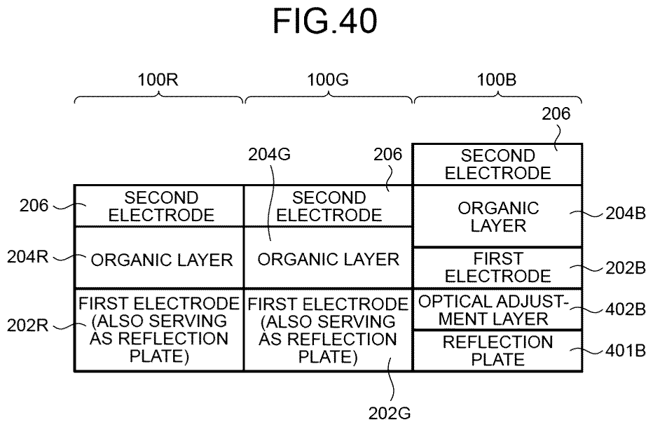

FIG. 40 is a schematic cross-sectional view for describing the seventh example of the resonator structure. In the seventh example, basically, the sixth example is applied to the subpixels 100R and 100G, and the first example is applied to the subpixel 100B. Also in this configuration, it is possible to set an optical distance for causing optimum resonance for a wavelength of light according to a color to be displayed.

The first electrodes (also serving as the reflection plates) 202R and 202G used in the subpixels 100R and 100G can be made of single metal such as aluminum (Al), silver (Ag), gold (Au), or copper (Cu), or an alloy containing these as main components.

Materials and the like constituting the reflection plate 401B, the optical adjustment layer 402B, and the first electrode 202B used in the subpixel 100B are similar to the content described in the first example, and thus the description thereof will be omitted.

### 6. Application Examples

For example, the technology according to the present disclosure may be applied to display units of various electronic devices and the like. Therefore, examples of an electronic device to which the present technology can be applied will be described below.

### First Specific Example

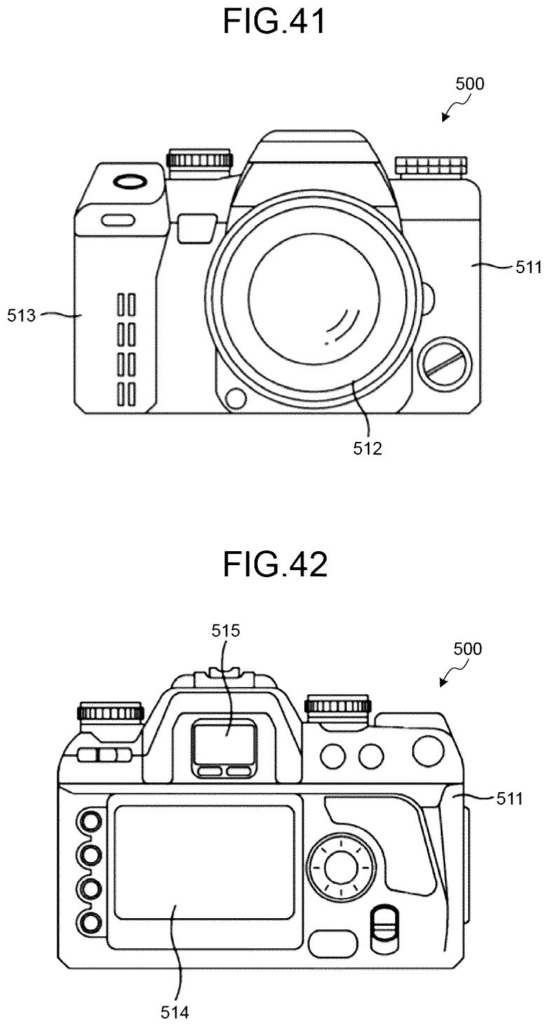

FIG. 41 is a front view illustrating an example of an external appearance of a digital still camera 500. FIG. 42 is a back view illustrating an example of the external appearance of the digital still camera 500. The digital still camera 500 is of a lens-interchangeable single-lens reflex type, and includes an interchangeable imaging lens unit (interchangeable lens) 512 substantially at the center of the front of a camera main body (camera body) 511 and includes, on the front left side, a grip portion 513 to be held by a photographer.

A monitor 514 is provided at a position deviated to the left from the center of the back of the camera main body 511. An electronic view finder (eyepiece window) 515 is provided above the monitor 514. The photographer can look into the electronic view finder 515 and visually recognize an optical image of a subject guided from the imaging lens unit 512 and determine composition. The display device 1 described above can be used as the monitor 514 and the electronic view finder 515.

### Second Specific Example

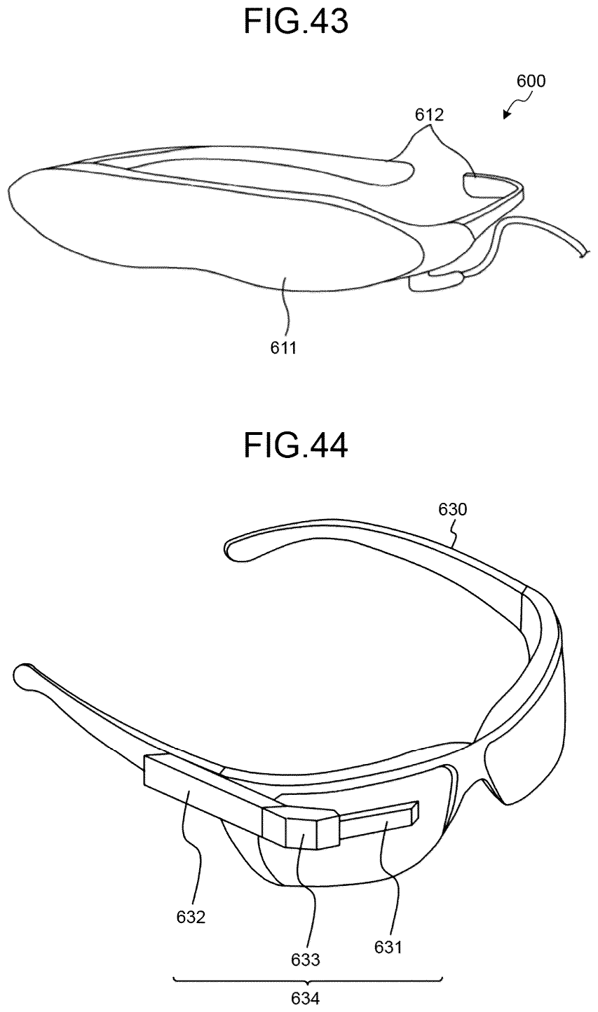

FIG. 43 is an external view of a head-mounted display 600. The head-mounted display 600 includes, for example, ear-hook portions 612 to be mounted on a head of a user on both sides of a display unit 611 formed in eyeglasses. In the head-mounted display 600, the display device 1 described above can be used as the display unit 611.

### Third Specific Example

FIG. 44 is an external view of a see-through head-mounted display 634. The see-through head-mounted display 634 includes a main body 632, an arm 633, and a lens barrel 631.

The main body 632 is connected to the arm 633 and glasses 630. Specifically, an end of the main body 632 in a long-side direction is coupled to the arm 633, and one side of a side surface of the main body 632 is coupled to the glasses 630 via a connecting member. Note that the main body 632 may be directly mounted on a head of a human body.

The main body 632 incorporates a display unit and a control board for controlling the operation of the see-through head-mounted display 634. The arm 633 connects the main body 632 and the lens barrel 631 and supports the lens barrel 631. Specifically, the arm 633 is coupled to the end of the main body 632 and an end of the lens barrel 631, and fixes the lens barrel 631. In addition, the arm 633 incorporates a signal line for communication of data related to an image provided from the main body 632 to the lens barrel 631.

The lens barrel 631 projects image light provided from the main body 632 via the arm 633 toward eyes of a user wearing the see-through head-mounted display 634 through an eyepiece. In the see-through head-mounted display 634, the display device 1 described above can be used for the display unit of the main body 632.

### Fourth Specific Example

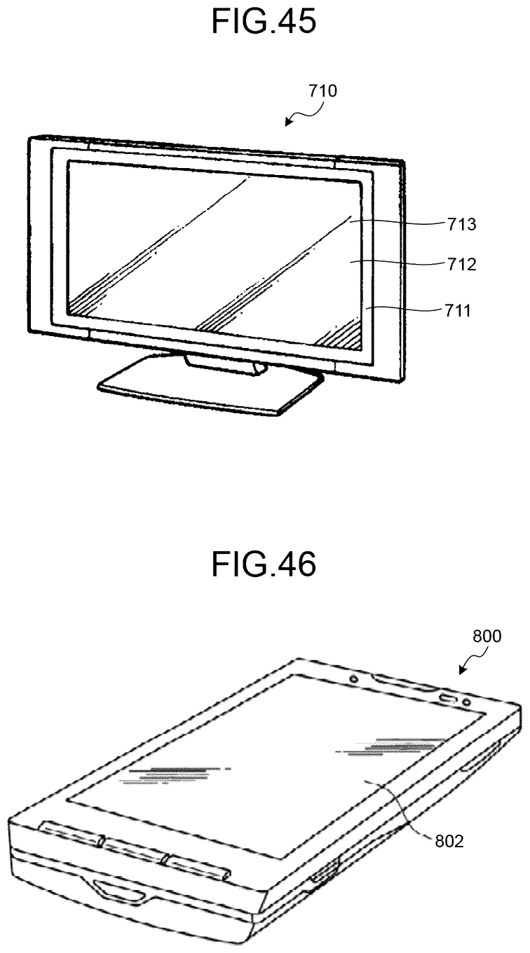

FIG. 45 illustrates an example of an external appearance of a television device 710. The television device 710 includes, for example, an image display screen unit 711 including a front panel 712 and a filter glass 713, and the image display screen unit 711 includes the display device 1 described above.

### Fifth Specific Example

FIG. 46 illustrates an example of an external appearance of a smartphone 800. The smartphone 800 includes a display unit 802 that displays various types of information, an operation unit including a button that receives an operation input by a user, and the like. The display unit 802 can be the display device 1 described above.

### Sixth Specific Example

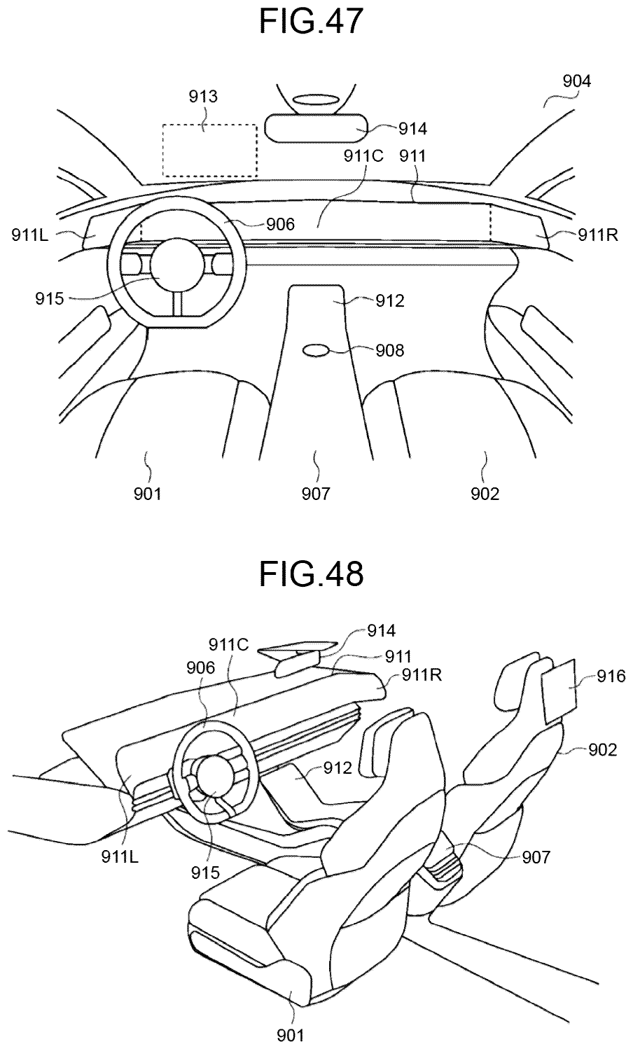

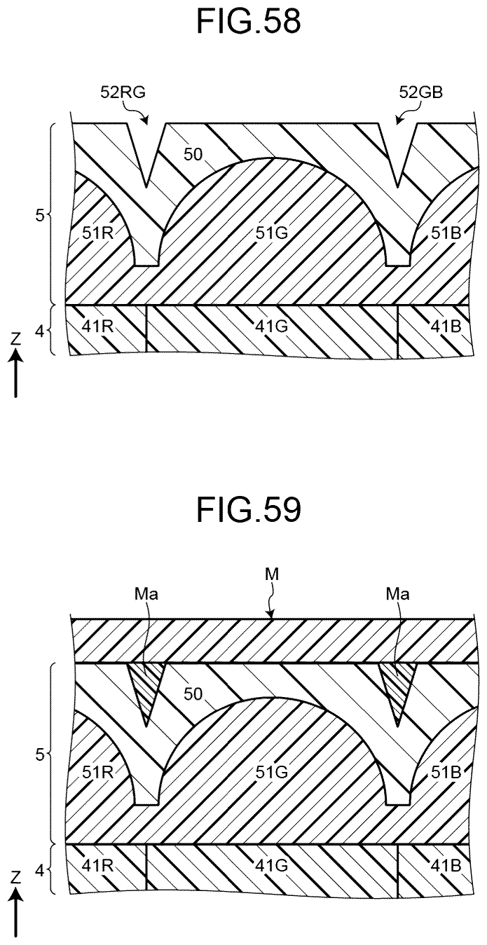

FIGS. 47 and 48 are views illustrating an internal configuration of an automobile including the display device 1 according to the embodiment of the present disclosure. Specifically, FIG. 59 is a view illustrating a state of the interior of the automobile from the rear to the front of the automobile, and FIG. 60 is a view illustrating a state of the interior of the automobile from the oblique rear to the oblique front of the automobile.

The automobile illustrated in FIGS. 47 and 48 includes a center display 911, a console display 912, a head-up display 913, a digital rear mirror 914, a steering wheel display 915, and a rear entertainment display 916. The display device 1 described above can be applied to some or all of these displays.

The center display 911 is arranged on a center console 907 at a place facing a driver's seat 901 and a passenger seat 902. FIGS. 59 and 60 illustrate an example of the center display 911 having a horizontally long shape extending from the driver's seat 901 side to the passenger seat 902 side, but a screen size and an arrangement place of the center display 911 are freely selected. The center display 911 can display information detected by various sensors (not illustrated). As a specific example, the center display 911 can display a captured image captured by an image sensor, a distance image to an obstacle in front of or on a side of the automobile measured by a time of flight (ToF) sensor, a body temperature of a passenger detected by an infrared sensor, and the like. The center display 911 can be used to display, for example, at least one of safety-related information, operation-related information, a life log, health-related information, authentication/identification-related information, and entertainment-related information.

The safety-related information is information such as doze detection, looking-away detection, mischief detection of a child riding together, presence or absence of wearing of a seat belt, and detection of leaving of an occupant, and is information detected by, for example, a sensor (not illustrated) arranged to overlap the back side of the center display 1911. The operation-related information detects gestures related to operations of an occupant using a sensor. The detected gestures may include operations on various types of equipment in the automobile. For example, operations on an air conditioner, a navigation device, an audio/visual (AV) device, a lighting device, and the like are detected. The life log includes a life log of all the occupants. For example, the life log includes an action record of each occupant on board. Since the life log is acquired and stored, it is possible to confirm a condition of an occupant in the event of an accident. As the health-related information, a body temperature of an occupant is detected using a temperature sensor, and a health condition of the occupant is estimated based on the detected body temperature. Alternatively, an image of a face of the occupant may be captured using an image sensor, and the health condition of the occupant may be estimated from a captured facial expression. Furthermore, a conversation may be made with the occupant in an automatic voice, and the health condition of the occupant may be estimated based on the content of an answer of the occupant. The authentication/identification-related information includes a keyless entry function of performing face authentication using a sensor, an automatic adjustment function of a height and a position of a seat by face identification, and the like. The entertainment-related information includes a function of detecting operation information of the AV device by an occupant using a sensor, a function of recognizing a face of the occupant by a sensor and providing content suitable for the occupant through the AV device, and the like.

The console display 912 can be used to display life log information, for example. The console display 912 is arranged near a shift lever 908 of the center console 907 between the driver's seat 901 and the passenger seat 902. The console display 912 can also display information detected by various sensors (not illustrated). In addition, the console display 912 may display an image of the periphery of s vehicle captured by an image sensor, or may display a distance image to an obstacle in the periphery of the vehicle.

The head-up display 913 is virtually displayed behind a windshield 904 in front of the driver's seat 901. The head-up display 913 can be used to display, for example, at least one of the safety-related information, the operation-related information, the life log, the health-related information, the authentication/identification-related information, and the entertainment-related information. The head-up display 913 is virtually arranged in front of the driver's seat 901 in many cases, and thus is suitable for displaying information directly related to an operation of the automobile such as a speed of the automobile and a remaining amount of fuel (a battery).

The digital rear mirror 914 can display not only the rear of the automobile but also a condition of an occupant in a rear seat, and thus can be used to display the life log information, for example, by arranging a sensor (not illustrated) to overlap the back side of the digital rear mirror 914.

The steering wheel display 915 is arranged near the center of a steering wheel 906 of the automobile. The steering wheel display 915 can be used to display, for example, at least one of the safety-related information, the operation-related information, the life log, the health-related information, the authentication/identification-related information, and the entertainment-related information. In particular, the steering wheel display 915 is close to a hand of a driver, and thus is suitable for displaying the life log information such as a body temperature of the driver, or for displaying information regarding the operation of the AV device, the air conditioner, or the like.

The rear entertainment display 916 is attached to the back side of the driver's seat 901 or the passenger seat 902, and is watched by an occupant in the rear seat. The rear entertainment display 916 can be used to display, for example, at least one of the safety-related information, the operation-related information, the life log, the health-related information, the authentication/identification-related information, and the entertainment-related information. In particular, the rear entertainment display 916 is in front of an eye of the occupant in the rear seat, and thus displays information related to the occupant in the rear seat. For example, information regarding the operation of the AV device or the air conditioner may be displayed, or a result of measuring a body temperature or the like of the occupant in the rear seat by a temperature sensor (not illustrated) may be displayed.

### 7. Further Embodiment

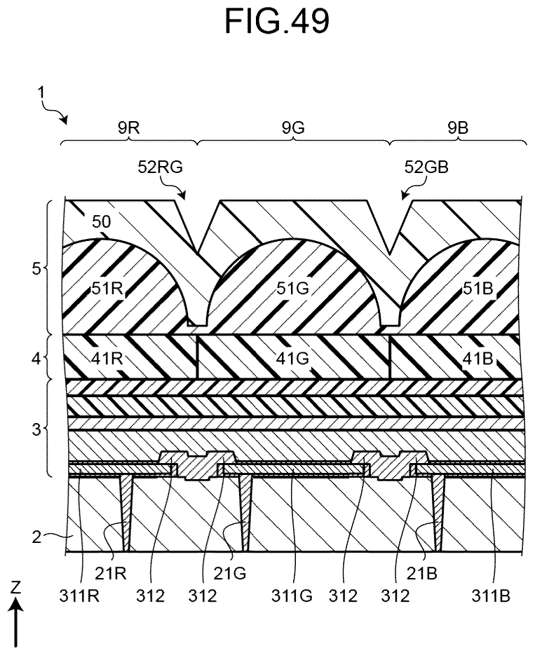

In the above-described embodiment, it has been described that the refractive index (hereinafter also referred to as “refractive index n₁”) of the auxiliary lens 52 may have a refractive index higher than the refractive index of the base portion 50 (hereinafter, also referred to as a “refractive index n₂”) (n₁>n₂). However, the same effects can be obtained even in a case where the refractive index n₁ of the auxiliary lens 52 is lower than the refractive index n₂ of the auxiliary lens 52 (n₁<n₂) Such an embodiment will be described with reference to FIGS. 49 to 72.

FIG. 49 is a view illustrating an example of a schematic configuration of a display device according to a further embodiment. The auxiliary lens 52 is formed using a low-refractive-index material having a lower refractive index than a material of the base portion 50. The refractive index n₁ of the auxiliary lens 52 is lower than the refractive index n₂ of the base portion 50.

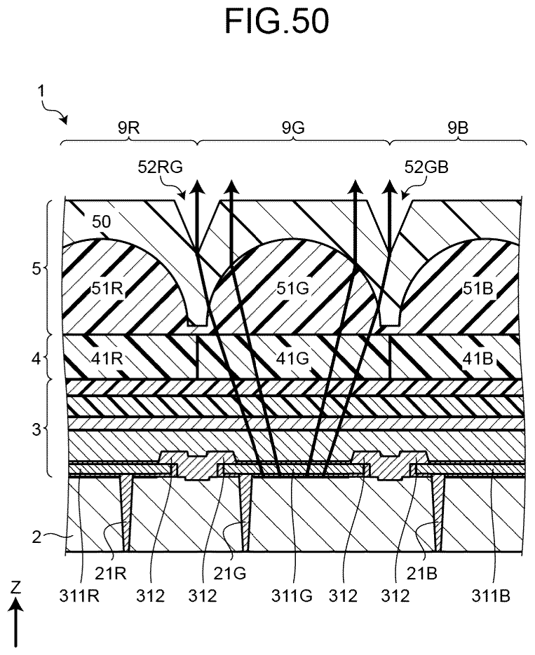

In this example, the auxiliary lens 52 is a void portion (also referred to as a slit or the like), and the refractive index n1 thereof may be the same as a refractive index of air. In addition, when the lens layer 5 is viewed from the side (viewed in a direction orthogonal to a Z-axis direction), the auxiliary lens 52 has an inverted triangular shape directed downward (in a Z-axis negative direction). Such an auxiliary lens 52 also improves the light extraction efficiency. Description will be made with reference to FIGS. 50 to 53.

FIGS. 50 to 53 are views illustrating examples of a traveling direction of light. As illustrated in FIG. 50, the traveling direction of light at an edge portion of the pixel 9G is brought close to a front direction (Z-axis positive direction) by the auxiliary lens 52, more specifically, the auxiliary lens 52RG and the auxiliary lens 52GB. Although not illustrated, the same applies to the pixel 9R and the pixel 9B.

FIG. 51 schematically illustrates a relationship between the refractive index of the auxiliary lens and the traveling direction of light. For convenience of description, among boundary surfaces of the auxiliary lens 52 with respect to the base portion 50, a surface located near the corresponding main lens 51 (surface on the main lens 51 side) is referred to as a boundary surface 52a. A boundary surface (boundary surface on a side opposite to the main lens 51) located apart from the corresponding main lens 51 is referred to as a boundary surface 52b. In addition, a normal line of the boundary surface 52a is virtually indicated by a one-dot chain line in the drawing. A traveling direction of light that has passed through the base portion 50 and been incident on the boundary surface 52a out of light from the main lens 51 is brought close to the front direction by the auxiliary lens 52.

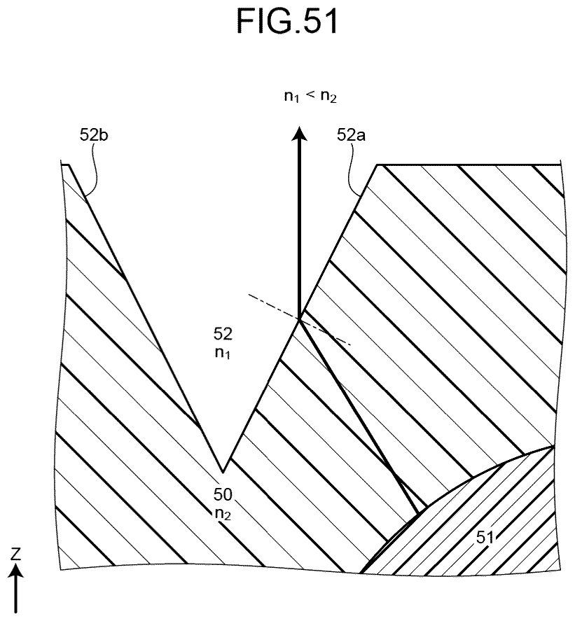

As a result, not only light at a central portion of the pixel 9G but also the light at the edge portion of the pixel 9G is extracted in the front direction of the pixel 9G as illustrated in FIG. 52. The same applies to the pixel 9R and the pixel 9B.

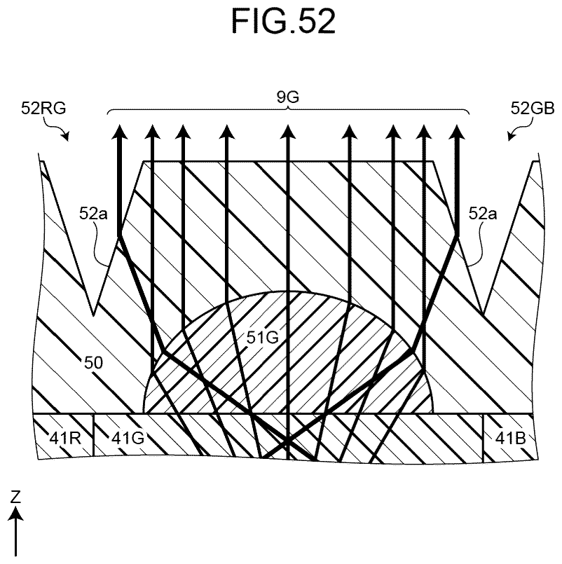

Note that, in a case where the refractive index n₁ of the auxiliary lens 52 is higher than the refractive index n₂ of the base portion 50 (n₁>n₂) as in the above-described embodiment (FIG. 1) and the like, a traveling direction of light incident on the boundary surface 52b out of the boundary surface 52a and the boundary surface 52b is brought close to the front direction by the auxiliary lens 52 as illustrated in FIG. 53.

FIGS. 54 to 61 are views illustrating examples of a manufacturing method of the display device. In particular, formation of the auxiliary lens 52 will be described.

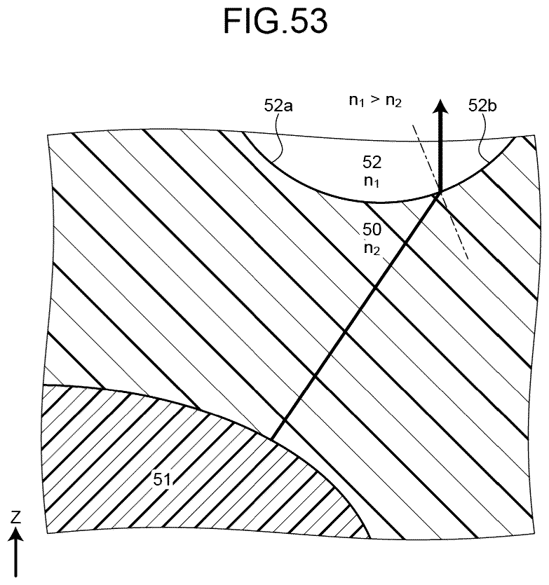

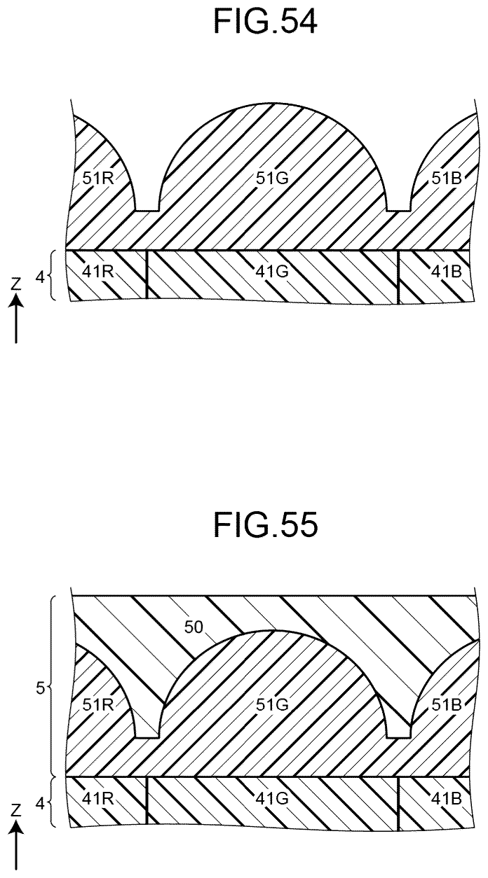

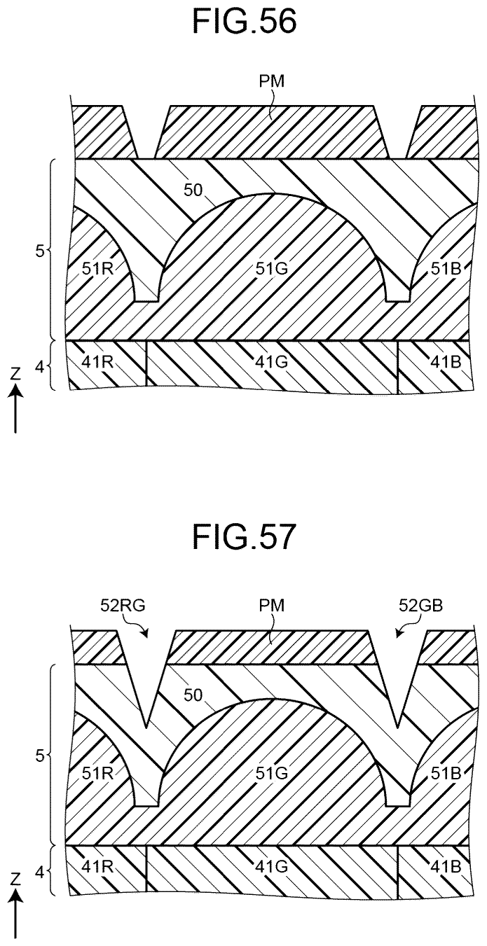

FIGS. 54 to 58 illustrate examples of the manufacturing method using an etching method. First, as illustrated in FIG. 54, the color filter layer 4 and the main lens 51 are formed using a known method. Furthermore, the base portion 50 is provided by depositing a material of the base portion 50 as illustrated in FIG. 55. The lens layer 5 in which the main lens 51 is embedded is obtained. As illustrated in FIG. 56, the photoresist material PM is arranged on the lens layer 5. The photoresist material PM is applied onto a part of the lens layer 5 so as to obtain a pattern of the auxiliary lens 52. For example, as illustrated in FIG. 57, the lens layer 5 is processed by dry etching, and the auxiliary lens 52 (in this example, the auxiliary lens 52RG and the auxiliary lens 52GB) is obtained. The photoresist material PM is removed, and the lens layer 5 including the auxiliary lens 52 is obtained as illustrated in FIG. 8. In a case where the auxiliary lens 52 has a configuration other than the void portion, a process for filling the void portion with a low refractive material may be further added.

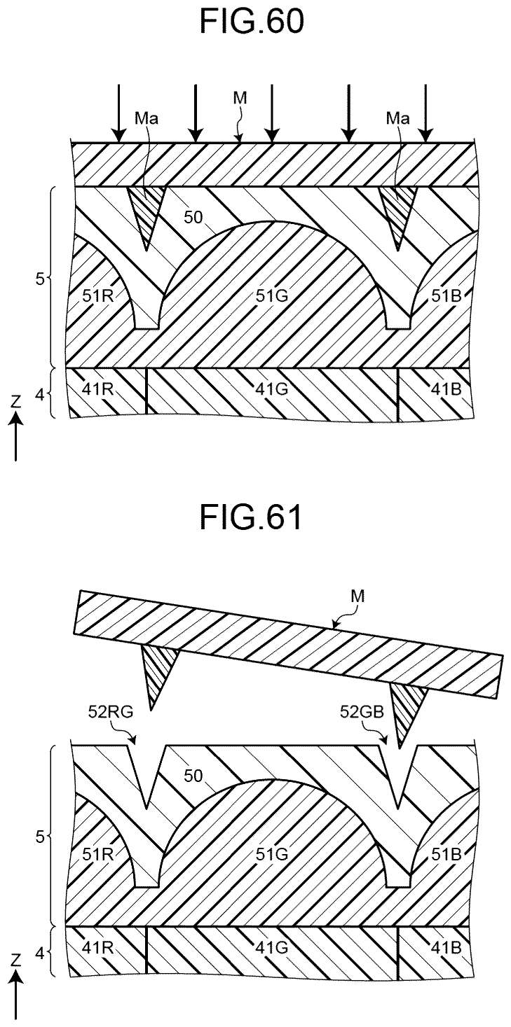

FIGS. 59 to 61 illustrate examples of the manufacturing method using an imprinting method. As a premise, it is assumed that a configuration similar to that in FIG. 55 described above has been obtained. However, a material of the base portion 50 is in a state before being applied and cured. As illustrated in FIG. 59, a mold M is pressed against the material of the base portion 50. The mold M has a protrusion Ma protruding downward (in the Z-axis negative direction). The protrusion Ma has the same shape as a shape of the auxiliary lens 52. In this state, ultraviolet rays are emitted to cure the material of the base portion 50 as illustrated in FIG. 60. Thereafter, when the mold M is removed as illustrated in FIG. 61, the lens layer 5 including the auxiliary lens 52 is obtained. In a case where the auxiliary lens 52 has a configuration other than the void portion, a process for filling the void portion with a low refractive material may be further added.

### 8. Variations of Cross-Sectional Structure

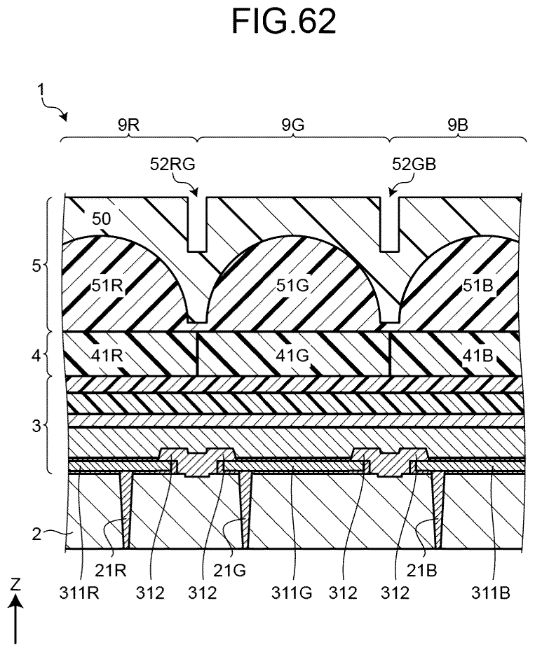

FIGS. 62 to 65 are views illustrating variations of a cross-sectional structure. In the side view of the lens layer 5, the auxiliary lens 52 has a rectangular shape. The exemplified rectangular shape is a rectangular shape whose longitudinal direction is the vertical direction (Z-axis direction).

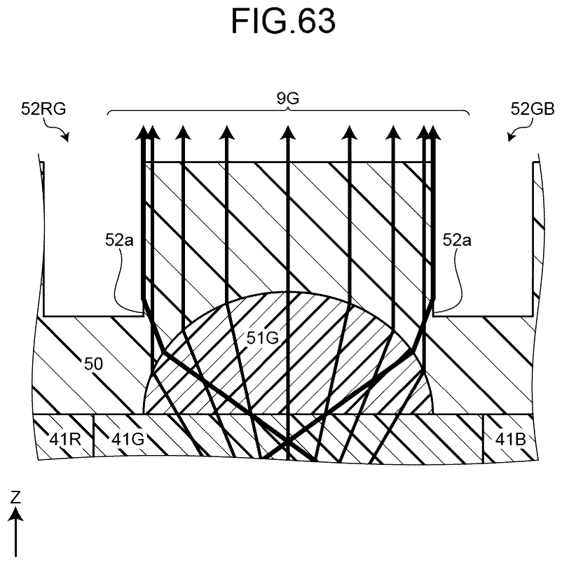

As illustrated in FIG. 63, light incident on the boundary surface 52a at a critical angle travels in the front direction. Therefore, the traveling direction of the light at the edge portion of the pixel 9G is brought close to the front direction by the auxiliary lens 52. The same applies to the pixel 9R and the pixel 9B.

In one embodiment, an additional auxiliary lens having a refractive index similar to that of the auxiliary lens 52 may be provided not only at an edge portion but also at a central portion of the pixel 9. Such an additional auxiliary lens is referred to as an auxiliary lens 53 to be distinguished from the auxiliary lens 52.

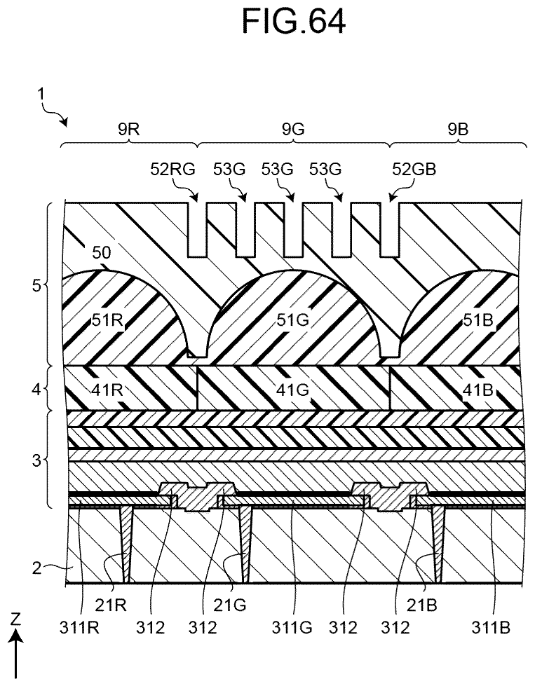

In an example illustrated in FIGS. 64 and 65, the lens layer 5 further includes the auxiliary lens 53. The auxiliary lens 53 is located immediately above the main lens 51. When the lens layer 5 is viewed in plan view (viewed in the Z-axis direction), the auxiliary lens 53 overlaps the main lens 51. Note that the auxiliary lens 53 provided immediately above the main lens 51 in the pixel 9G is referred to as an auxiliary lens 53G in the drawing. Although not illustrated, the additional auxiliary lenses 53 may be similarly provided in the pixel 9R and the pixel 9G, which may be referred to as an auxiliary lens 53R and an auxiliary lens 53G, respectively.

Even in a case where light incident on the auxiliary lens 53 includes light whose traveling direction is deviated from the front direction, a traveling direction of the light is brought close to the front direction by the auxiliary lens 53. This increases the possibility that the light extraction efficiency can be further improved. In the example illustrated in FIGS. 64 and 65, a plurality of the auxiliary lenses 53 are provided for one main lens 51. An effect obtained by the auxiliary lens 53 can be improved as compared with a case where only one auxiliary lens 53 is provided.

Note that, in addition to the above, the variations (FIGS. 9 to 17) of the cross-sectional structure of the embodiment described above may be used in combination as long as there is no contradiction.

### 9. Variations of Planar Layout

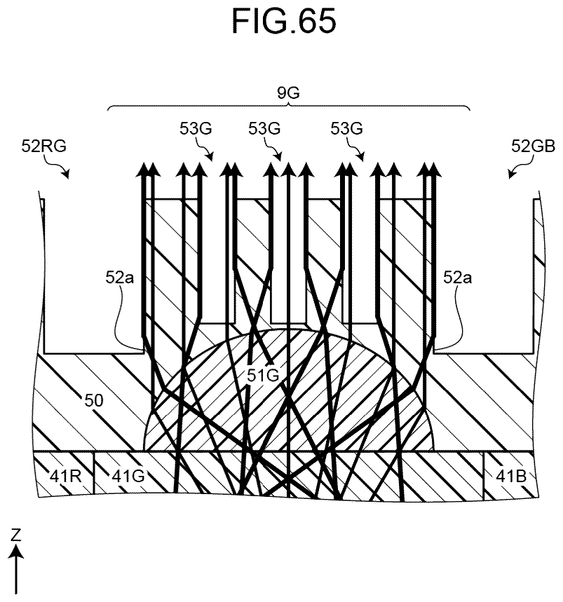

FIGS. 66 to 72 are views illustrating variations of a planar layout.

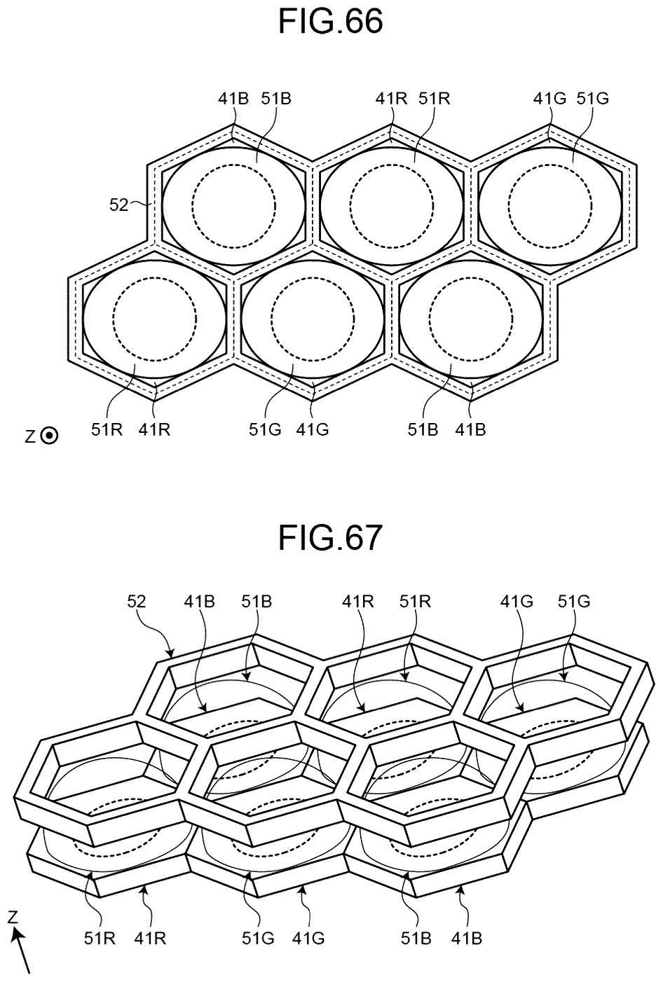

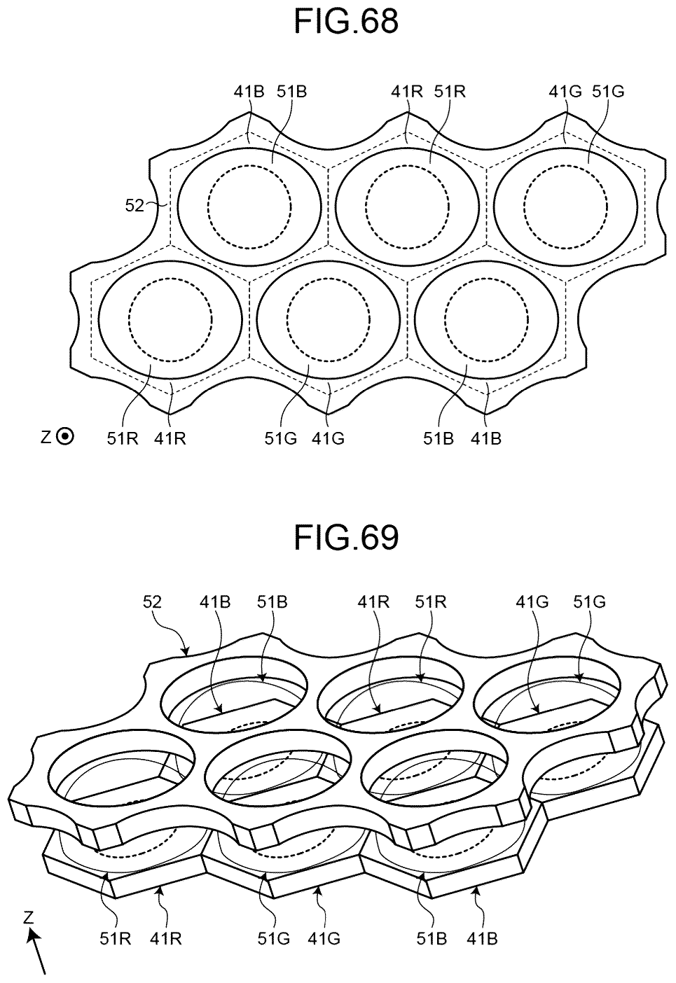

In examples illustrated in FIGS. 66 to 69, the auxiliary lens 52 has an annular shape surrounding the main lens 51 when the lens layer 5 is viewed in plan view (viewed in the Z-axis direction). The annular shape may be a rectangular annular shape as illustrated in FIGS. 66 and 67 (in this example, a hexagonal annular shape), or may be a circular annular shape as illustrated in FIGS. 68 and 69.

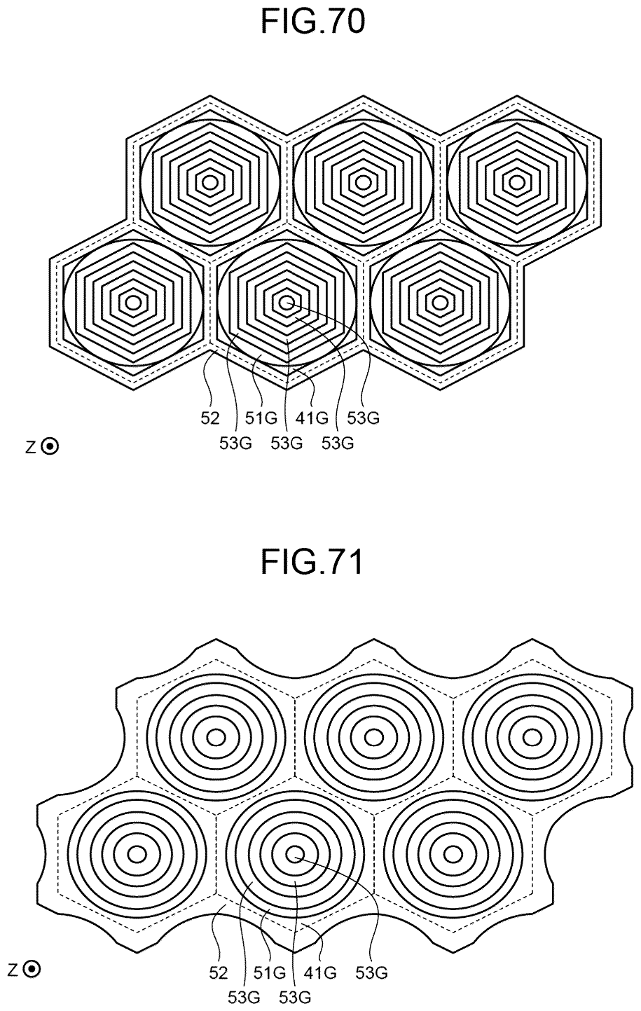

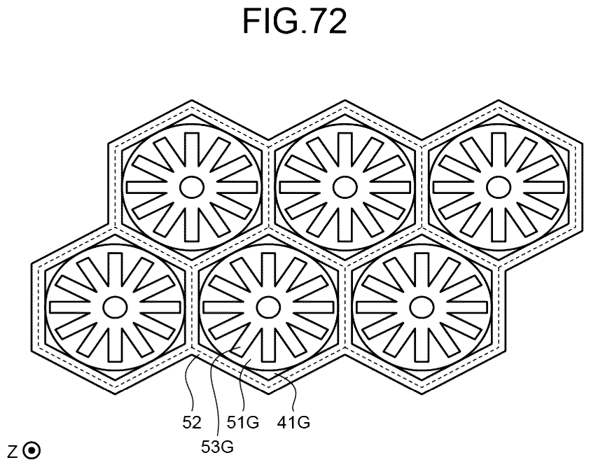

FIGS. 70 to 72 illustrate examples of the planar layout including the auxiliary lens 53. In the example illustrated in FIGS. 70 and 71, the auxiliary lens 53 has an annular shape, for example, a rectangular annular shape or a circular annular shape similarly to the auxiliary lens 52. In the example illustrated in FIG. 72, the auxiliary lens 53 has a radial shape extending radially from the center of the main lens 51.

Note that, in addition to the above, the variations (FIGS. 18 to 26) of the planar layout of the embodiment described above may be used in combination as long as there is no contradiction.

The technology according to the further embodiment described above is specified as follows, for example. As described with reference to FIGS. 49 to 52, 62 to 72, and the like, the auxiliary lens 52 may have the refractive index n₁ lower than the refractive index n₂ of a portion (the base portion 50) between the auxiliary lens 52 and the main lens 51 in the lens layer 5. The light extraction efficiency can also be improved by such an auxiliary lens 52.

As described with reference to FIGS. 49, 62, and the like, the auxiliary lens 52 may have a triangular shape or a rectangular shape in the side view of the lens layer 5 is viewed from the side. For example, since the auxiliary lens 52 having such a shape is used, the light extraction efficiency can be improved even in a case where the refractive index n₁ of the auxiliary lens 52 is low.

In addition, as described with reference to FIGS. 64, 65, 70 to 72, and the like, the lens layer 5 may include the auxiliary lens 53 (additional auxiliary lens) provided on the side opposite to the light emitting element layer 3 across the array of the plurality of main lenses 51, the auxiliary lens 53 may have the refractive index n₂ lower than the refractive index n₁ of the portion (base portion 50) between the auxiliary lens 53 and the main lens 51 in the lens layer 5 and may have the rectangular shape in the side view of the lens layer 5, and the auxiliary lens 53 may overlap the main lens 51 in the plan view of the lens layer 5. In the plan view of the lens layer 5, the auxiliary lens 53 may have an annular shape or a radial shape. Since such an auxiliary lens 53 is provided, the possibility that the light extraction efficiency can be further improved increases as compared with a case where only the main lens 51 and the auxiliary lens 52 are provided.

Note that the effects described in the present disclosure are merely examples and are not limited to the disclosed content. There may be other effects.

Although the above description is given regarding the embodiments of the present disclosure, the technical scope of the present disclosure is not limited to the above-described embodiments as they are, and various modifications can be made without departing from the scope of the present disclosure. In addition, constituent elements in different embodiments and modifications can be combined suitably.

Note that the present technology can also have the following configurations.

(1) A display device comprising:
a light emitting element layer provided on a base; and
a lens layer provided on a side opposite to the base across the light emitting element layer,
wherein the lens layer includes:
   a plurality of main lenses arranged in an array in a plane direction of the lens layer; and
   an auxiliary lens provided on a side opposite to the light emitting element layer across the array of the plurality of main lenses, and
the auxiliary lens is located between adjacent main lenses among the plurality of main lenses in a plan view of the lens layer.
   (2) The display device according to (1), wherein
the main lenses bring a traveling direction of light from the light emitting element layer close to a front direction of the display device, and
the auxiliary lens brings a traveling direction of light from the main lenses close to the front direction.
   (3) The display device according to (1) or (2), wherein
the auxiliary lens has a refractive index higher than a refractive index of a portion between the auxiliary lens and the main lenses in the lens layer.
   (4) The display device according to (1) or (2), wherein
the auxiliary lens has a refractive index lower than a refractive index of a portion between the auxiliary lens and the main lenses in the lens layer.
   (5) The display device according to (4), wherein
the auxiliary lens has a triangular shape or a rectangular shape in a side view of the lens layer.
   (6) The display device according to (4) or (5), wherein
the lens layer includes an additional auxiliary lens provided on the side opposite to the light emitting element layer across the array of the plurality of main lenses,
the additional auxiliary lens has a refractive index lower than a refractive index of a portion between the additional auxiliary lens and the main lenses in the lens layer, and has a rectangular shape in a side view of the lens layer, and
the additional auxiliary lens overlaps the main lenses in the plan view of the lens layer.
   (7) The display device according to (6), wherein
the additional auxiliary lens has an annular shape or a radial shape in the plan view of the lens layer.
   (8) The display device according to any one of (1) to (7), wherein
the main lenses are provided for pixels, respectively, and
the auxiliary lens is located at edge portions of the pixels in the plan view of the lens layer.
   (9) The display device according to any one of (1) to (8), wherein
a part of the auxiliary lens overlaps a part of at least one main lens of the corresponding adjacent main lenses in the plan view of the lens layer.
   (10) The display device according to any one of (1) to (9), wherein
one auxiliary lens is provided as the auxiliary lens located between the adjacent main lenses in the plan view of the lens layer.
   (11) The display device according to any one of (1) to (9), wherein
two or more auxiliary lenses are provided as the auxiliary lens located between the adjacent main lenses in the plan view of the lens layer.
   (12) The display device according to any one of 1 to 3 and 8 to 11, but excluding the features referred to in 4-7, wherein
the auxiliary lens has a convex shape protruding toward the array of the plurality of main lenses.
   (13) The display device according to (12), wherein
the convex shape of the auxiliary lens includes at least one of a semicircular shape, a triangular shape, and a trapezoidal shape.
   (14) The display device according to any one of (1) to (13), wherein
the auxiliary lens has an annular shape surrounding each of the main lenses in the plan view of the lens layer.
   (15) The display device according to (14), wherein
the annular shape of the auxiliary lens includes at least one of a circular annular shape and a rectangular annular shape.
   (16) The display device according to any one of (1) to (15), wherein
the lens layer further includes a plurality of second main lenses that are provided on a side opposite to the auxiliary lens across the array of the plurality of main lenses and correspond to the plurality of main lenses.
   (17) The display device according to (16), wherein
the lens layer further includes a second auxiliary lens provided on a side opposite to the auxiliary lens across an array of the plurality of second main lenses.
   (18) The display device according to any one of (1) to (17), further comprising
a color filter layer provided between the light emitting element layer and the lens layer.

### REFERENCE SIGNS LIST

1 DISPLAY DEVICE
2 BASE
21 CONTACT PLUG
21R CONTACT PLUG
21G CONTACT PLUG
21B CONTACT PLUG
3 LIGHT EMITTING ELEMENT LAYER
31 ELECTRODE LAYER
311 ELECTRODE
311R ELECTRODE
311G ELECTRODE
311B ELECTRODE
312 ELECTRODE EDGE FILM
32 ELECTRODE LAYER
33 ORGANIC LAYER
34 PROTECTIVE LAYER
35 PLANARIZATION LAYER
4 COLOR FILTER LAYER
41 COLOR FILTER
41R COLOR FILTER
41G COLOR FILTER
41B COLOR FILTER
5 LENS LAYER
51R MAIN LENS
51G MAIN LENS
51B MAIN LENS
51-2R MAIN LENS
51-2G MAIN LENS
51-2B MAIN LENS
52RG AUXILIARY LENS
52GB AUXILIARY LENS
52RB AUXILIARY LENS
52-2RG AUXILIARY LENS
52-2GB AUXILIARY LENS
52a BOUNDARY SURFACE
52b BOUNDARY SURFACE
53 AUXILIARY LENS (ADDITIONAL AUXILIARY LENS)
53G AUXILIARY LENS
9 PIXEL
9R PIXEL
9G PIXEL
9B PIXEL
PM PHOTORESIST MATERIAL
M MOLD
Ma PROTRUSION

1. A display device comprising:
a light emitting element layer provided on a base; and
a lens layer provided on a side opposite to the base across the light emitting element layer,
wherein the lens layer includes:
a plurality of main lenses arranged in an array in a plane direction of the lens layer; and
an auxiliary lens provided on a side opposite to the light emitting element layer across the array of the plurality of main lenses, and
the auxiliary lens is located between adjacent main lenses among the plurality of main lenses in a plan view of the lens layer.

2. The display device according to claim 1, wherein
the main lenses bring a traveling direction of light from the light emitting element layer close to a front direction of the display device, and
the auxiliary lens brings a traveling direction of light from the main lenses close to the front direction.

3. The display device according to claim 1, wherein
the auxiliary lens has a refractive index higher than a refractive index of a portion between the auxiliary lens and the main lenses in the lens layer.

4. The display device according to claim 1, wherein
the auxiliary lens has a refractive index lower than a refractive index of a portion between the auxiliary lens and the main lenses in the lens layer.

5. The display device according to claim 4, wherein
the auxiliary lens has a triangular shape or a rectangular shape in a side view of the lens layer.

6. The display device according to claim 4, wherein
the lens layer includes an additional auxiliary lens provided on the side opposite to the light emitting element layer across the array of the plurality of main lenses,
the additional auxiliary lens has a refractive index lower than a refractive index of a portion between the additional auxiliary lens and the main lenses in the lens layer, and has a rectangular shape in a side view of the lens layer, and
the additional auxiliary lens overlaps the main lenses in the plan view of the lens layer.

7. The display device according to claim 6, wherein
the additional auxiliary lens has an annular shape or a radial shape in the plan view of the lens layer.

8. The display device according to claim 1, wherein
the main lenses are provided for pixels, respectively, and
the auxiliary lens is located at edge portions of the pixels in the plan view of the lens layer.

9. The display device according to claim 1, wherein
a part of the auxiliary lens overlaps a part of at least one main lens of the corresponding adjacent main lenses in the plan view of the lens layer.

10. The display device according to claim 1, wherein
one auxiliary lens is provided as the auxiliary lens located between the adjacent main lenses in the plan view of the lens layer.

11. The display device according to claim 1, wherein
two or more auxiliary lenses are provided as the auxiliary lens located between the adjacent main lenses in the plan view of the lens layer.

12. The display device according to claim 1, wherein
the auxiliary lens has a convex shape protruding toward the array of the plurality of main lenses.

13. The display device according to claim 12, wherein
the convex shape of the auxiliary lens includes at least one of a semicircular shape, a triangular shape, and a trapezoidal shape.

14. The display device according to claim 1, wherein
the auxiliary lens has an annular shape surrounding each of the main lenses in the plan view of the lens layer.

15. The display device according to claim 14, wherein
the annular shape of the auxiliary lens includes at least one of a circular annular shape and a rectangular annular shape.

16. The display device according to claim 1, wherein
the lens layer further includes a plurality of second main lenses that are provided on a side opposite to the auxiliary lens across the array of the plurality of main lenses and correspond to the plurality of main lenses.

17. The display device according to claim 16, wherein
the lens layer further includes a second auxiliary lens provided on a side opposite to the auxiliary lens across an array of the plurality of second main lenses.

18. The display device according to claim 1, further comprising
a color filter layer provided between the light emitting element layer and the lens layer.
